(19) United States
(12) Patent Application Publication
(10) Pub. No.: US 2026/0239593 A1
(43) Pub. Date: Aug. 13, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Kouhei TOYOTAKA, Isehara, Kanagawa (JP); Yuto YAKUBO, Atsugi, Kanagawa (JP)

(21) Appl. No.: 19/475,095

(22) PCT Filed: Apr. 22, 2024
(86) PCT No.: PCT/IB2024/053879

§ 371 Date: Oct. 14, 2025

(30) Foreign Application Priority Data
Apr. 28, 2023 (JP) 2023-074198

(51) Int. Cl. H10B 10/00

(52) U.S. Cl. CPC H10B 10/125

(57) ABSTRACT

A semiconductor device with high reliability is provided. A latch circuit including Si transistors is combined with a memory circuit including OS transistors. A soft error is less likely to occur in the memory circuit including OS transistors. The logic value of the latch circuit and the logic value of the memory circuit including OS transistors are compared and a comparison result is output. The logic value of the latch circuit is inverted in accordance with the comparison result. High-speed operation by the latch circuit including Si transistors and high reliability by the memory circuit including OS transistors are achieved.

### TECHNICAL FIELD

One embodiment of the present invention relates to a semiconductor device.

One embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof.

### BACKGROUND ART

In recent years, the amount of data subjected to processing has been increasing, which makes a demand for a memory device having a higher memory capacity. Furthermore, a memory device that does not easily allow data loss due to a soft error and has high reliability has been required. A soft error is a defect that part of data stored in a memory device is inverted (bit inversion) unintentionally by radiation. Examples of radiation include electromagnetic waves (electromagnetic radiation) typified by X-rays and gamma rays and particle radiation typified by alpha rays, beta rays, neutron beams, proton beams, heavy-ion beams, and meson beams. In particular, radiation that is assumed to be derived from outer space is also referred to as “cosmic rays”. A soft error caused by radiation is also referred to as an SEU (Single Event Upset).

A defect in which a 1-bit soft error occurs in one word (a piece of data) is referred to as SBU (Single Bit Upset). A defect in which soft errors of a plurality of bits occur in one word is referred to as MBU (Multi Bit Upset).

A soft error does not cause physical damage and thus is easily recovered. For example, an ECC (Error Check and Correct) memory that achieves SBU error detection and data correction is known. The ECC memory is used, for example, for an electronic device where occurrence of data error is forbidden, such as a computer used for scientific computation or used in a financial institution.

However, it is difficult for the ECC memory to perform correction of data with MBU. As a countermeasure against MBU, memory scrubbing which corrects data at the stage of SBU is known. In addition, in Patent Document 1, an ECC memory is disclosed in which one word to be stored is divided into a plurality of pieces and a correction code (also referred to as “check data” or “check bit”) is added for each of the divided pieces to deal with MBU.

### REFERENCE

### Patent Document [Patent Document 1] Japanese Translation of PCT International Application No. H5-508042

### SUMMARY OF THE INVENTION

### Problems to be Solved by the Invention

The ECC memory calculates a check bit corresponding to data of one word and stores the data and the check bit in combination. Accordingly, the amount of data stored in a physical memory is increased, and practically usable memory capacity is reduced. In addition, in the case of executing the above-described memory scrubbing, writing back one corresponding word or writing back all words connected to one word line is needed to correct 1-bit data, which increases power consumption. As the execution frequency of memory scrubbing is increased to deal with MBU, power consumption increases accordingly.

One object of one embodiment of the present invention is to provide a semiconductor device capable of correcting data with MBU. Another object of one embodiment of the present invention is to provide a highly reliable semiconductor device. Another object of one embodiment of the present invention is to provide a semiconductor device with low power consumption. Another object of one embodiment of the present invention is to provide a novel semiconductor device.

Note that the objects of one embodiment of the present invention are not limited to the objects listed above. The objects listed above do not preclude the existence of other objects. Note that the other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

(1) One embodiment of the present invention is a semiconductor device including a first memory circuit and a second memory circuit. The semiconductor device has a function of comparing a logic value of first data retained in the first memory circuit with a logic value of second data retained in the second memory circuit and a function of outputting a first signal corresponding to a comparison result. The first memory circuit includes a transistor including silicon in a channel formation region. The second memory circuit includes a transistor including an oxide semiconductor in a channel formation region.

In (1), the semiconductor device of one embodiment of the present invention has a function of outputting a potential H when the logic value of the first data and the logic value of the second data are different from each other.

(2) Another embodiment of the present invention is a semiconductor device including a first memory circuit and a second memory circuit. The first memory circuit includes a first inverter circuit, a second inverter circuit, a first transistor, and a second transistor. An output of the first inverter circuit is electrically connected to an input of the second inverter circuit. An output of the second inverter circuit is electrically connected to an input of the first inverter circuit. The output of the first inverter circuit is electrically connected to a first wiring through a source and a drain of the first transistor. The output of the second inverter circuit is electrically connected to a second wiring through a source and a drain of the second transistor. The second memory circuit includes a third transistor to a seventh transistor and a capacitor. One of a source and a drain of the third transistor is electrically connected to the output of the first inverter circuit and one of a source and a drain of the fourth transistor. The other of the source and the drain of the third transistor is electrically connected to one terminal of the capacitor and a gate of the fourth transistor. One of a source and a drain of the fifth transistor is electrically connected to the output of the second inverter circuit and one of a source and a drain of the sixth transistor. The other of the source and the drain of the fifth transistor is electrically connected to the other terminal of the capacitor and a gate of the sixth transistor. A gate of the third transistor is electrically connected to a gate of the fifth transistor. The other of the source and the drain of the fourth transistor and the other of the source and the drain of the sixth transistor are electrically connected to one of a source and a drain of the seventh transistor. The other of the source and the drain of the seventh transistor is electrically connected to a third wiring.

It is preferable that the first inverter circuit include a transistor including silicon in a channel formation region, the second inverter circuit include a transistor including silicon in a channel formation region, and the third transistor and the fifth transistor be each a transistor including an oxide semiconductor in a channel formation region. Alternatively, a transistor including an oxide semiconductor in a channel formation region may be used as each of the third transistor to the seventh transistor.

In (2), the semiconductor device of one embodiment of the present invention has a function of outputting a potential H when a potential of the output of the first inverter circuit is a potential H and a potential of the gate of the fourth transistor is a potential H. In (2), the semiconductor device of one embodiment of the present invention has a function of outputting a potential L when a potential of the output of the first inverter circuit is a potential L and a potential of the gate of the fourth transistor is a potential H.

In each of (1) and (2), the first memory circuit and the second memory circuit preferably overlap with each other in a region. When the first memory circuit and the second memory circuit overlap with each other, the area occupied by the semiconductor device can be reduced.

### EFFECT OF THE INVENTION

According to one embodiment of the present invention, error correction can be performed without adding a check bit to data of one word. Thus, according to one embodiment of the present invention, error correction can be achieved without increasing the amount of data stored in a physical memory. Thus, a reduction in practically usable memory capacity in a semiconductor device, such as a physical memory, can be prevented.

In addition, according to one embodiment of the present invention, a semiconductor device capable of correcting data with MBU can be provided. According to one embodiment of the present invention, a highly reliable semiconductor device can be provided. According to one embodiment of the present invention, a semiconductor device with low power consumption can be provided. According to one embodiment of the present invention, a novel semiconductor device can be provided.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1 is a diagram illustrating a semiconductor device.

FIG. 2 is a diagram illustrating a semiconductor device.

FIG. 3 is a diagram illustrating a semiconductor device.

FIG. 4A and FIG. 4B are diagrams illustrating a semiconductor device.

FIG. 5 is a timing chart showing operation of a semiconductor device.

FIG. 6 is a diagram illustrating operation of a semiconductor device.

FIG. 7 is a diagram illustrating operation of a semiconductor device.

FIG. 8 is a diagram illustrating operation of a semiconductor device.

FIG. 9 is a diagram illustrating operation of a semiconductor device.

FIG. 10 is a diagram illustrating operation of a semiconductor device.

FIG. 11 is a diagram illustrating operation of a semiconductor device.

FIG. 12 is a diagram illustrating operation of a semiconductor device.

FIG. 13 is a diagram illustrating a semiconductor device.

FIG. 14A to FIG. 14D are diagrams each illustrating a semiconductor device.

FIG. 15 is a diagram illustrating a semiconductor device.

FIG. 16A is a flowchart showing operation of a semiconductor device. FIG. 16B is a diagram illustrating the operation of the semiconductor device.

FIG. 17A is a flowchart showing operation of a semiconductor device. FIG. 17B is a diagram illustrating the operation of the semiconductor device.

FIG. 18 is a flowchart showing operation of a semiconductor device.

FIG. 19A to FIG. 19C are diagrams each illustrating operation of a semiconductor device.

FIG. 20 is a flowchart showing operation of a semiconductor device.

FIG. 21A to FIG. 21C are diagrams each illustrating operation of a semiconductor device.

FIG. 22 is a diagram illustrating a planar structure example of a semiconductor device.

FIG. 23A and FIG. 23B are diagrams illustrating a cross-sectional structure example of a semiconductor device.

FIG. 24A to FIG. 24E are diagrams illustrating structure examples of a transistor.

FIG. 25A and FIG. 25B are diagrams illustrating structure examples of a transistor.

FIG. 26 is a diagram illustrating a structure example of a semiconductor device.

FIG. 27A to FIG. 27J are diagrams illustrating examples of electronic devices.

FIG. 28A to FIG. 28C are diagrams illustrating an example of an electronic device.

FIG. 29 is a diagram illustrating an example of an electronic device.

### MODE FOR CARRYING OUT THE INVENTION

Embodiments will be described below with reference to the drawings. Note that the embodiments can be implemented in many different modes, and it is readily understood by those skilled in the art that modes and details can be changed in various ways without departing from the spirit and scope. Thus, the present invention should not be construed as being limited to the description of the embodiments below.

In this specification and the like, a semiconductor device refers to a device that utilizes semiconductor characteristics, and means a circuit including a semiconductor element (e.g., a transistor, a diode, or a photodiode) a device including the circuit, and the like. The semiconductor device also means any device that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, an electronic device, and the like themselves are semiconductor devices and also include a semiconductor device.

In the drawings and the like in this specification, the size, the layer thickness, or the region is exaggerated for clarity in some cases. Thus, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings.

Note that in the structures of the invention in the embodiments, the same reference numeral is used in common for the same portions or portions having similar functions in different drawings, and repeated description thereof is omitted. Furthermore, the same hatch pattern is used for the portions having similar functions, and the portions are not especially denoted by reference numerals in some cases. Moreover, some components are omitted in a perspective view, a plan view, and the like for easy understanding of the drawings in some cases.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims.

In this specification and the like, the terms for describing positioning, such as “over”, “under” “above”, and “below”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

The term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and does not exclude the state where the electrode B is formed under the insulating layer A or the state where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification and the like, the terms “film”, “layer”, and the like can be interchanged with each other depending on the situation. For example, the term “conductive layer” can be replaced with the term “conductive film” in some cases. As another example, the term “insulating film” can be changed to the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. Alternatively, the term “conductor” can be changed into the term “conductive layer” or “conductive film” in some cases. As another example, the term “insulating layer” or “insulating film” can be changed into the term “insulator” in some cases. Alternatively, the term “insulator” can be changed into the term “insulating layer” or “insulating film” in some cases.

Note that voltage refers to a difference between potentials of two points, and a potential refers to electrostatic energy (electric potential energy) of a unit charge at a given point in an electrostatic field. In general, a difference between a potential of one point and a reference potential (e.g., a ground potential) is merely called a potential or a voltage, and a potential and a voltage are used as synonyms in many cases. Thus, in this specification and the like, potential is interchangeable with voltage and voltage is interchangeable with potential unless explicitly stated.

In this specification and the like, the term “electrode”, “wiring”, “terminal”, or the like does not limit the function of a component. For example, an “electrode” is used as part of a “wiring” in some cases, and vice versa. Furthermore, the term “electrode” or “wiring” also includes the case where a plurality of “electrodes” or “wirings” are formed in an integrated manner, for example. As another example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”, and a “terminal” can be part of a “wiring” or an “electrode”. Moreover, the terms “electrode”, “wiring”, “terminal”, and the like are sometimes replaced with the term “region” or the like depending on the case.

In this specification and the like, the terms “wiring”, “signal line”, “power supply line”, and the like can be interchanged with each other depending on the case or the situation. For example, the term “wiring” can be changed into the term “signal line” in some cases. For another example, the term “wiring” can be changed into the term “power supply line” or the like in some cases. Conversely, the term “signal line”, “power supply line”, or the like can be changed into the term “wiring” in some cases. The term “power supply line” or the like can be changed to the term “signal line” or the like in some cases. Conversely, the term “signal line” or the like can be changed to the term “power supply line” or the like in some cases. The term “potential” that is applied to a wiring can be changed to the term “signal” or the like depending on the case or the situation. Conversely, the term “signal” or the like can be changed to the term “potential” in some cases.

In this specification, an explicit description that X and Y are connected includes the case where X and Y are electrically connected, the case where X and Y are functionally connected, and the case where X and Y are directly connected. Here, X and Y each denote an object (e.g., a device, an element, a circuit, a wiring, an electrode, a terminal, a conductive film, or a layer). Accordingly, without being limited to a predetermined connection relation, for example, a connection relation shown in drawings or text, a connection relation other than the connection relation shown in drawings or text is also included.

For example, in the case where X and Y are electrically connected, one or more elements that allow electrical connection between X and Y (e.g., a switch, a transistor, a capacitor, an inductor, and a resistor) can be connected between X and Y.

For example, in the case where X and Y are functionally connected, one or more circuits that allow functional connection between X and Y (for example, a logic circuit (an inverter, a NAND circuit, a NOR circuit, or the like); a signal converter circuit (a DA converter circuit, an AD converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; or a control circuit) can be connected between X and Y. For instance, even if another circuit is sandwiched between X and Y, X and Y are regarded as being functionally connected when a signal output from X is transmitted to Y.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the terms “identical”, “the same”, “equal”, “uniform”, and the like (including synonyms thereof) used in describing calculation values and measurement values contain an error of ±20 % unless otherwise specified.

In the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, a semiconductor layer 163 is referred to as a semiconductor layer 163[1], a semiconductor layer 163[2], and the like in some cases.

### Embodiment 1

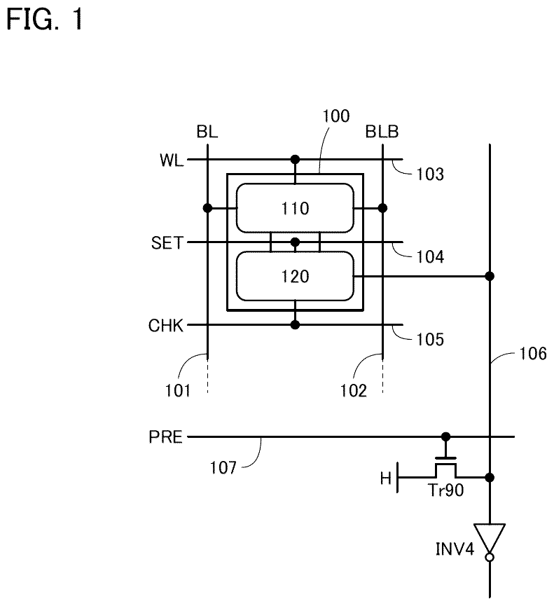

A memory cell 100 of one embodiment of the present invention is described. FIG. 1 is a diagram illustrating a structure example of the memory cell 100, which is a kind of semiconductor device. The memory cell 100 includes a first memory circuit 110 and a second memory circuit 120. The first memory circuit 110 and the second memory circuit 120 each have a function of retaining 1-bit data.

The memory cell 100 has a function of comparing the logic value of data retained in the first memory circuit 110 and the logic value of data retained in the second memory circuit 120 and outputting a comparison result as a first signal.

### Circuit Structure Example

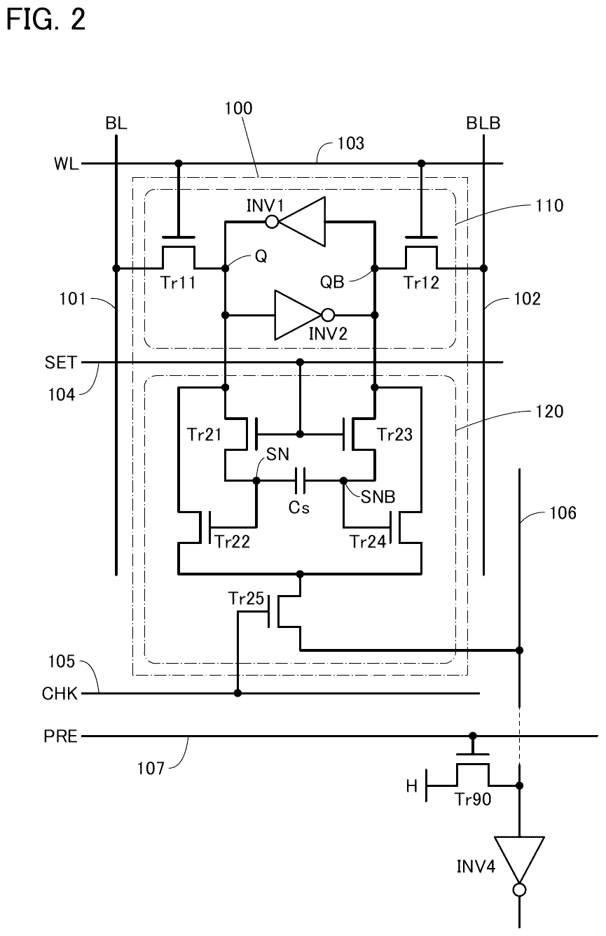

FIG. 2 illustrates a specific circuit structure example of the memory cell 100. The first memory circuit 110 includes an inverter circuit INV1, an inverter circuit INV2, a transistor Tr11, and a transistor Tr12. An output of the inverter circuit INVI is connected to an input of the inverter circuit INV2, and an output of the inverter circuit INV2 is connected to an input of the inverter circuit INV1.

One of a source and a drain of the transistor Tr11 is connected to a wiring 101, and the other of the source and the drain is connected to the output of the inverter circuit INV1 and the input of the inverter circuit INV2. One of a source and a drain of the transistor Tr12 is connected to the output of the inverter circuit INV2 and the input of the inverter circuit INV1. The other of the source and the drain of the transistor Tr12 is connected to a wiring 102. A gate of the transistor Tr11 and the gate of the transistor Tr11 are electrically connected to a wiring 103. The first memory circuit 110 functions as a latch circuit. Thus, the memory cell 100 also functions as a latch circuit.

In this specification and the like, a region where the output of the inverter circuit INV1, the input of the inverter circuit INV2, and the other of the source and the drain of the transistor Tr11 are connected to each other is referred to as a “node Q”. In this specification and the like, a region where the output of the inverter circuit INV2, the input of the inverter circuit INV1, and the one of the source and the drain of the transistor Tr12 are connected to each other is referred to as a “node QB”.

The second memory circuit 120 includes a transistor Tr21 to a transistor Tr25 and a capacitor Cs. One of a source and a drain of the transistor Tr21 is connected to the output of the inverter circuit INV1, the input of the inverter circuit INV2, the other of the source and the drain of the transistor Tr11, and one of a source and a drain of the transistor Tr22. The other of the source and the drain of the transistor Tr21 is electrically connected to a gate of the transistor Tr22 and one terminal of the capacitor Cs.

One of a source and a drain of the transistor Tr23 is connected to the output of the inverter circuit INV2, the input of the inverter circuit INV1, the one of the source and the drain of the transistor Tr12, and one of a source and a drain of the transistor Tr24. The other of the source and the drain of the transistor Tr23 is connected to a gate of the transistor Tr24 and the other electrode of the capacitor Cs. A gate of the transistor Tr21 and a gate of the transistor Tr23 are connected to a wiring 104.

The other of the source and the drain of the transistor Tr22 and the other of the source and the drain of the transistor Tr24 are electrically connected to one of a source and a drain of the transistor Tr25. The other of the source and the drain of the transistor Tr25 is connected to a wiring 106, and a gate of the transistor Tr25 is connected to a wiring 105. The second memory circuit 120 functions as an error sensing circuit. Thus, the memory cell 100 functions as a latch circuit having an error sensing function.

In this specification and the like, a region where the other of the source and the drain of the transistor Tr21, the one terminal of the capacitor Cs, and the gate of the transistor Tr22 are connected to each other is referred to as a “node SN”. In this specification and the like, a region where the other of the source and the drain of the transistor Tr23, the other terminal of the capacitor Cs, and the gate of the transistor Tr24 are connected to each other is referred to as a “node SNB”.

The wiring 106 is connected to an input of an inverter circuit INV4. The wiring 106 is connected to one of a source and a drain of a transistor Tr90. A potential H is supplied to the other of the source and the drain of the transistor Tr90. A gate of the transistor Tr90 is connected to a wiring 107.

A signal BL is supplied to the wiring 101, a signal BLB is supplied to the wiring 102, and a signal WL is supplied to the wiring 103. A signal SET is supplied to the wiring 104, a signal CHK is supplied to the wiring 105, and a signal PRE is supplied to the wiring 107.

As a semiconductor layer where the channel of the transistor included in the first memory circuit 110 is formed, a single crystal semiconductor, a polycrystalline semiconductor, a microcrystalline semiconductor, an amorphous semiconductor, or the like can be used alone or in combination. As a semiconductor material, silicon or germanium can be used, for example. Alternatively, a compound semiconductor such as silicon germanium, silicon carbide, or gallium arsenide may be used.

The inverter circuit INV 1, the inverter circuit INV2, the transistor Tr11, and the transistor Tr12 included in the first memory circuit 110 are preferably transistors each including silicon in a channel formation region (also referred to as a “Si transistor”), for example. A Si transistor using a single crystal semiconductor or a polycrystalline semiconductor as a semiconductor where a channel is formed is particularly preferable. A Si transistor using a single crystal semiconductor or a polycrystalline semiconductor has excellent productivity because of relatively easy manufacture process and operates fast. On the other hand, a soft error is likely to occur in a memory circuit or a memory element using a Si transistor (also referred to as a “Si memory”) even though data reading speed and data writing speed thereof are high.

As each of the transistor Tr11 and the transistor Tr12, either an n-channel transistor or a p-channel transistor can be used.

Among the transistor Tr21 to the transistor Tr25 that are included in the second memory circuit 120, it is particularly preferable to use OS transistors as the transistor Tr21 and the transistor Tr23. Although an OS transistor has lower operation speed than a Si transistor, an OS transistor has a band gap greater than or equal to 2 eV and thus has an extremely low off-state current. Thus, data written to the node SN and the node SNB of the second memory circuit 120 can be retained for a long time. Note that as each of the transistor Tr22, the transistor Tr24, and the transistor Tr25, not only an OS transistor but also a transistor other than an OS transistor can be used.

In addition, an OS transistor operates stably even in a high-temperature environment and has small change in characteristics. For example, the off-state current hardly increases even in a high-temperature environment. Specifically, the off-state current hardly increases even at an environment temperature higher than or equal to room temperature and lower than or equal to 200° C. In addition, the on-state current is less likely to decrease even in a high-temperature environment. Thus, a memory circuit or a memory element using an OS transistor (also referred to as an “OS memory”) can operate stably and have high reliability even in a high-temperature environment.

A change in electrical characteristics of an OS memory due to irradiation with radiation such as cosmic rays is small. In other words, a soft error due to radiation is unlikely to occur, and thus the reliability of the memory cell 100 can be increased.

The memory cell 100 is a memory element including a Si memory and an OS memory. A combination of a Si memory with high operation speed and an OS memory with high reliability can achieve a highly reliable memory device with high operation speed.

### Variation Example

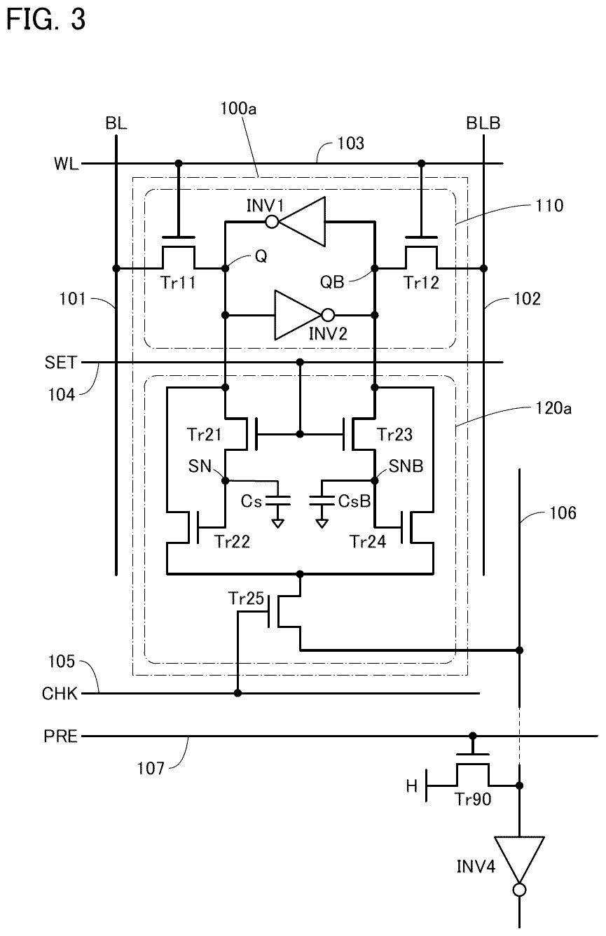

FIG. 3 illustrates a circuit structure example of a memory cell 100a, which is a variation example of the memory cell 100. The memory cell 100a includes a second memory circuit 120a instead of the second memory circuit 120.

The second memory circuit 120a includes a capacitor CsB in addition to the capacitor Cs. One terminal of the capacitor CsB is electrically connected to the other of the source or the drain of the transistor Tr23. In the second memory circuit 120a, a region where the other of the source and the drain of the transistor Tr23, the one terminal of the capacitor CsB, and the gate of the transistor Tr24 are connected to each other is referred to as the “node SNB”.

In the second memory circuit 120a, a power supply potential or a fixed potential is supplied to each of the other terminal of the capacitor Cs and the other terminal of the capacitor CsB. In the second memory circuit 120a, the number of circuit elements is increased because of the capacitor CsB as compared with that in the second memory circuit 120. However, since it becomes possible to supply a power supply potential or a fixed potential to each of the other terminal of the capacitor Cs and the other terminal of the capacitor CsB, the potentials of the node SN and the node SNB become more stable than those in the second memory circuit 120. Consequently, the memory cell 100a can have higher reliability.

Note that in this specification and the like, “memory cell 100” can be replaced with “memory cell 100a” in some cases. In this specification and the like, “second memory circuit 120” can be replaced with “second memory circuit 120a” in some cases.

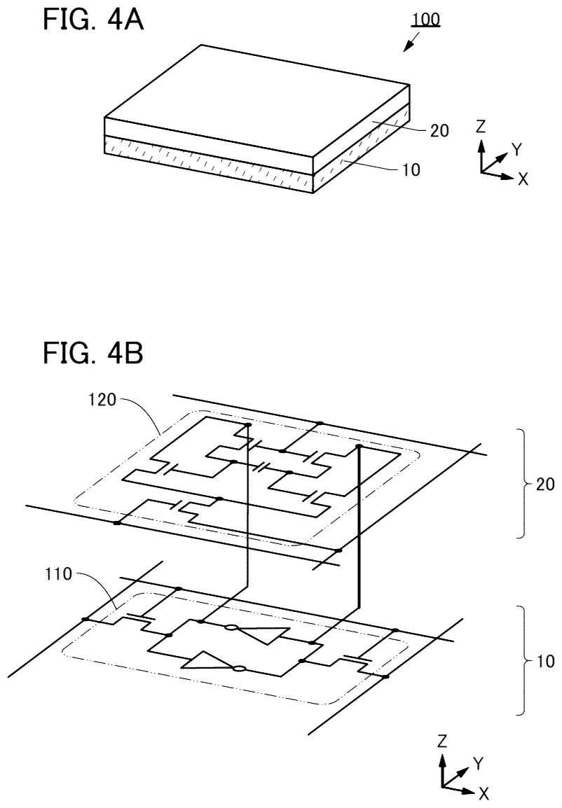

The memory cell 100 may be provided such that the first memory circuit 110 and the second memory circuit 120 overlap with each other. When the first memory circuit 110 and the second memory circuit 120 are provided to overlap with each other, the area occupied by the memory cell 100 can be reduced. FIG. 4A is a perspective view of the memory cell 100. FIG. 4B is a perspective view for explaining the structure of the memory cell 100, illustrating a layer 10 and a layer 20 separately.

The layer 10 includes the first memory circuit 110. The layer 20 includes the second memory circuit 120. For example, a single crystal silicon substrate may be used as the layer 10 and the first memory circuit 110 may be formed on the silicon substrate. When the channel formation region of the Si transistor included in the first memory circuit 110 is formed using the silicon substrate, a single crystal Si transistor that includes a single crystal semiconductor in the channel formation region and operates at high speed can be formed.

For example, an SOI (Silicon On Insulator) substrate or the like may be used as the layer 10. As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A Si transistor manufactured using an SOI substrate can have reduced parasitic capacitance and operate at high speed.

Moreover, an OS transistor is a thin film transistor and thus can be provided to be stacked over the layer 10 as the layer 20. In addition, the OS transistor operates stably even in a high-temperature environment and has small change in characteristics as described above. Thus, even when the second memory circuit 120 including the OS transistor is provided over the first memory circuit 110 including the Si transistor to overlap with the first memory circuit 110, the second memory circuit 120 is less likely to be affected by heat generated by the first memory circuit 110 and can have high reliability.

### Operation Example

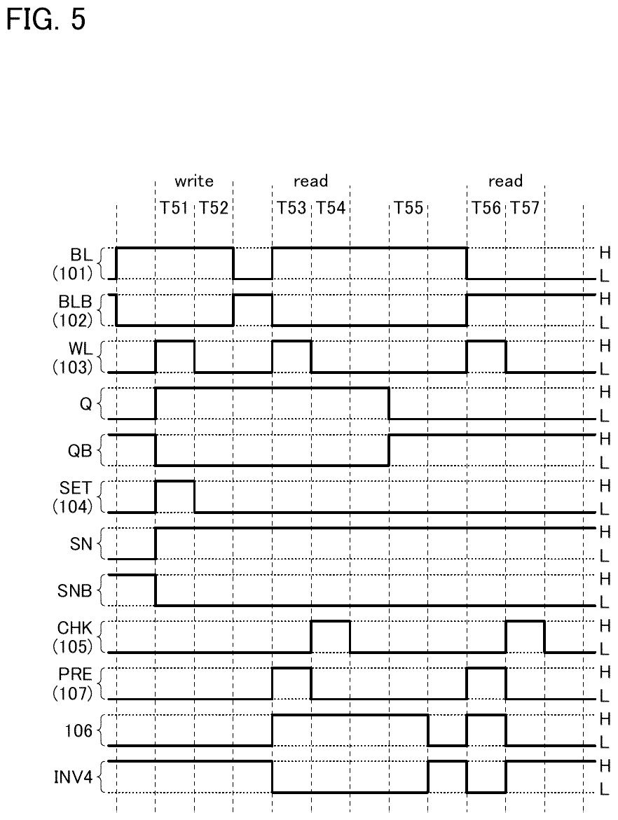

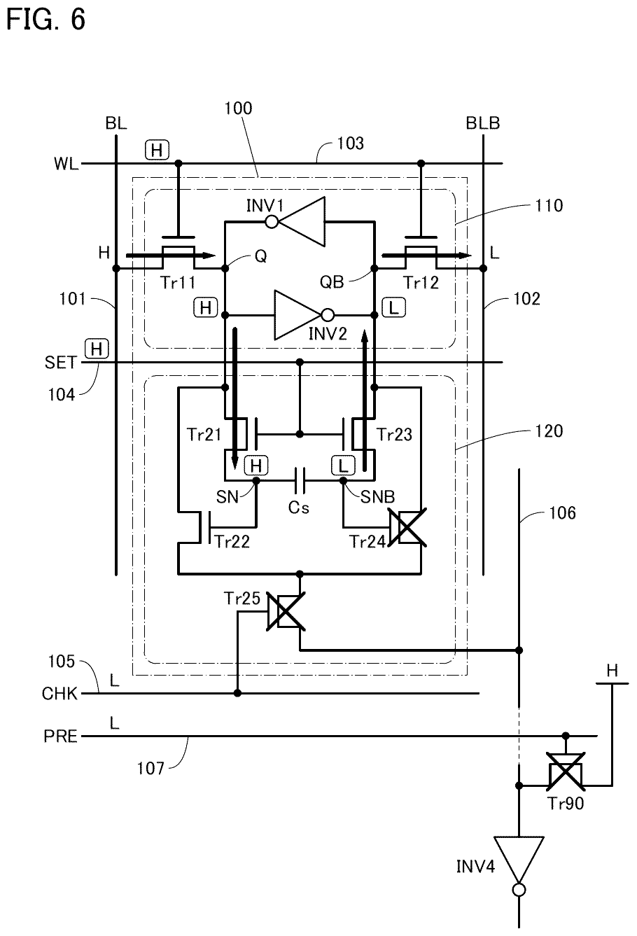

Next, operation of the memory cell 100 is described. FIG. 5 is a timing chart showing operation of the memory cell 100. FIG. 6 to FIG. 12 are circuit diagrams each illustrating an operation state of the memory cell 100.

Note that in this specification and the like, a potential that can turn off an n-channel transistor is referred to as a potential L. The potential L may be, for example, a low power supply potential VSS, but does not mean a particular potential. Also in this specification and the like, a potential that can turn on an n-channel transistor is referred to as a potential H. The potential H may be, for example, a high power supply potential VDD, but does not mean a particular potential. Note that the high power supply potential VDD is a potential higher than the low power supply potential VSS.

For example, in the case of description “potential L is supplied” to each of two wirings, the potentials L supplied to the two wirings are not necessarily equal to each other. Similarly, in the case of description “potential H is supplied” to each of two wirings, the potentials H supplied to the two wirings are not necessarily equal to each other.

In the drawings and the like, a symbol showing a potential (also referred to as a “potential symbol”) such as “H” or “L” is sometimes illustrated adjacent to a terminal, a wiring, or the like. In addition, arrows indicating the direction and path of current flow are illustrated in some cases. For easy understanding of changes in potentials of terminals, wirings, and the like, a potential symbol of a terminal, a wiring, or the like whose potential has changed is sometimes enclosed. Furthermore, a symbol “x” sometimes overlaps with an off-state transistor.

### Data Writing Operation

Operation of writing data to the memory cell 100 is described.

In this specification and the like, the state where the potential of the node Q is the potential H indicates that data “1” is written to or retained in the first memory circuit 110 as a logic value. That is, the state where the potential of the output of the inverter circuit INVI is the potential H indicates that data “1” is written to or retained in the first memory circuit 110 as a logic value.

The state where the potential of the node Q is the potential L indicates that data “0” is written to or retained in the first memory circuit 110 as a logic value. That is, the state where the potential of the output of the inverter circuit INVI is the potential L indicates that data “0” is written to or retained in the first memory circuit 110 as a logic value.

In this specification and the like, the state where the potential of the node SN is the potential H indicates that data “1” is written to or retained in the second memory circuit 120 as a logic value. That is, the state where the potential of the gate of the transistor Tr22 is the potential H indicates that data “1” is written to or retained in the second memory circuit 120 as a logic value.

In this specification and the like, the state where the potential of the node SN is the potential L indicates that data “0” is written to or retained in the second memory circuit 120 as a logic value. That is, the state where the potential of the gate of the transistor Tr22 is the potential L indicates that data “0” is written to or retained in the second memory circuit 120 as a logic value.

Immediately before the start of data writing operation, the signal BL, the node QB, and the node SNB are each at the potential H. The signal BLB, the signal WL, the node Q, the signal SET, the node SN, the signal CHK, the signal PRE, and the output of the inverter circuit INV4 are each at the potential L.

In Period T51, the signal WL and the signal SET are set to the potential H (see FIG. 5 and FIG. 6). When the signal WL becomes the potential H, the transistor Tr11 and the transistor Tr12 are turned on, so that the potential H is supplied to the node Q and the potential L is supplied to the node QB. When the signal SET becomes the potential H, the transistor Tr21 and the transistor Tr23 are turned on, so that the potential H is supplied to the node SN and the potential L is supplied to the node SNB.

When the potential H is supplied to the node SN, the transistor Tr22 is turned on. When the potential L is supplied to the node SNB, the transistor Tr24 is turned off.

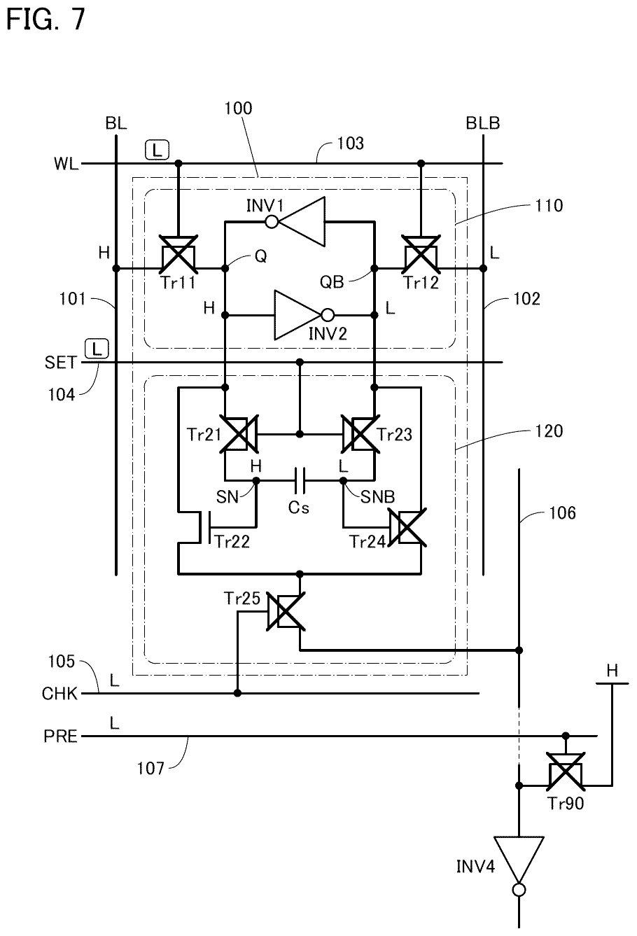

In Period T52, the signal WL and the signal SET are set to the potential L (see FIG. 5 and FIG. 7). When the signal WL becomes the potential L, the transistor Tr11 and the transistor Tr12 are turned off. When the signal SET becomes the potential L, the transistor Tr21 and the transistor Tr23 are turned off.

When the transistor Tr11 and the transistor Tr12 are turned off, the potential of the node Q is fixed at the potential H and the potential of the node QB is fixed at the potential L. When the transistor Tr21 and the transistor Tr23 are turned off, the node SN and the node SNB are brought into a floating state (electrically floating state), and the potentials written to the node SN and the node SNB in Period T51 are retained. In this manner, the same data is retained in both the first memory circuit 110 and the second memory circuit 120.

### Data Reading Operation

Next, operation of reading data retained in the memory cell 100 is described. Here, data whose logic value is “1” has been written to the memory cell 100. That is, the data whose logic value is “1” is retained in both the first memory circuit 110 and the second memory circuit 120.

Case Where Soft Error Does Not Occur First, reading operation in the case where a soft error does not occur in the memory cell 100 is described. Immediately before the start of the reading operation (immediately before Period T53), the signal WL is at the potential L and the potential of the wiring 106 is the potential L. The wiring 101 is at the potential L and in a floating state. The wiring 102 is at the potential H and in a floating state.

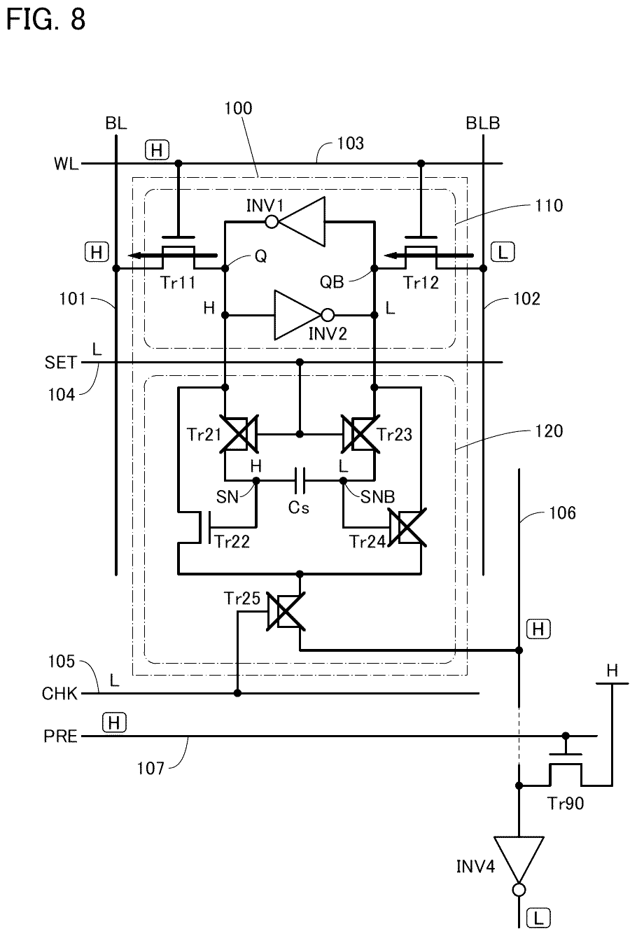

In Period T53, the signal WL and the signal PRE are set to the potential H (see FIG. 5 and FIG. 8). When the signal WL becomes the potential H, the transistor Tr11 and the transistor Tr12 are turned on. When the transistor Tr11 is turned on, the output potential of the inverter circuit INVI is supplied to the wiring 101. When the transistor Tr12 is turned on, the output potential of the inverter circuit INV2 is supplied to the wiring 102. By detecting the potentials of the wiring 101 and the wiring 102, data retained in the memory cell 100 can be read.

When the signal PRE becomes the potential H, the transistor Tr90 is turned on and the potential H is precharged to the wiring 106. That is, when the transistor Tr90 is turned off after the potential of the wiring 106 becomes the potential H, the wiring 106 is brought into a floating state while the potential thereof remains the potential H. When the potential of the wiring 106 becomes the potential H, the output potential of the inverter circuit INV4 becomes the potential L.

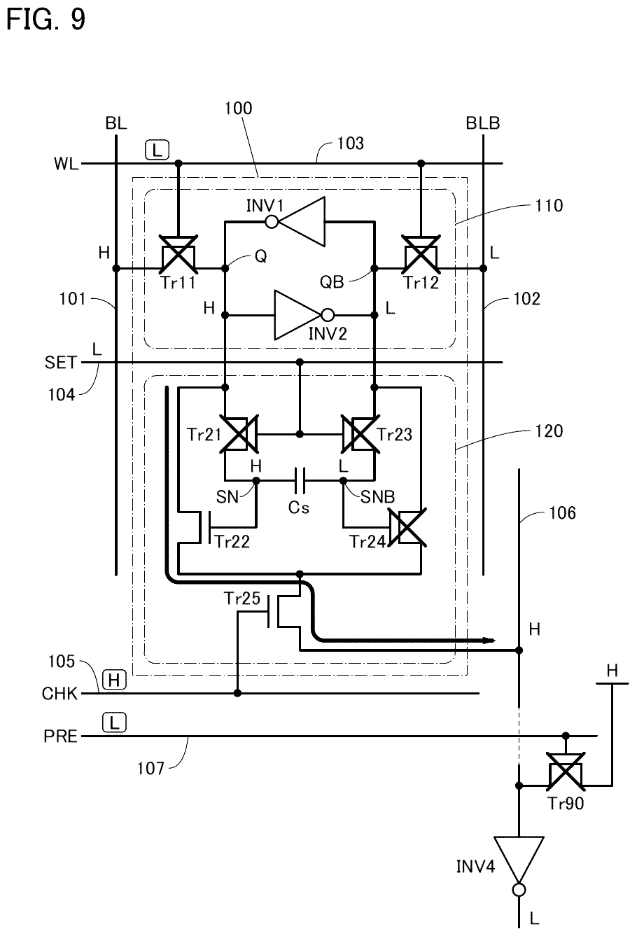

Next, in Period T54, the signal WL and the signal PRE are set to the potential L, and the signal CHK is set to the potential H (see FIG. 5 and FIG. 9). When the signal WL becomes the potential L, the transistor Tr11 and the transistor Tr12 are turned off. When the signal PRE becomes the potential L, the transistor Tr90 is turned off. Note that in Period T54, the signal WL may remain at the potential H continuously from Period T53.

When the signal CHK becomes the potential H, the transistor Tr25 is turned on. At this time, since the potential of the node SN is the potential H, the transistor Tr22 is in an on state. The output potential of the inverter circuit INV1 (which is the same as the potential of the node Q here) is supplied to the wiring 106 through the transistor Tr22 and the transistor Tr25.

In Period T54, the output potential of the inverter circuit INV1 is the potential H, and the potential of the wiring 106 is also the potential H; thus, the output of the inverter circuit INV4 remains the potential L. When the logic value of data retained in the first memory circuit 110 (also referred to as “first data”) and the logic value of data retained in the second memory circuit 120 (also referred to as “second data”) are equal to each other, the potential H is output as the first signal from the memory cell 100 to the wiring 106. In addition, the potential L is output from the inverter circuit INV4.

Note that in the case where a transistor with high operation speed, such as a Si transistor, is used as each of the transistor Tr22, the transistor Tr24, and the transistor Tr25, the above precharge operation is not necessarily performed. Even in the case where a transistor with low operation speed, such as an OS transistor, is used as each of the transistor Tr22, the transistor Tr24, and the transistor Tr25, when data reading can take time, the above precharge operation is not necessarily performed. In the case where the precharge operation is not performed, the wiring 107 and the transistor Tr90 are not necessarily provided.

### Case Where Soft Error Occurs

Next, reading operation in the case where a soft error occurs in the memory cell 100 is described.

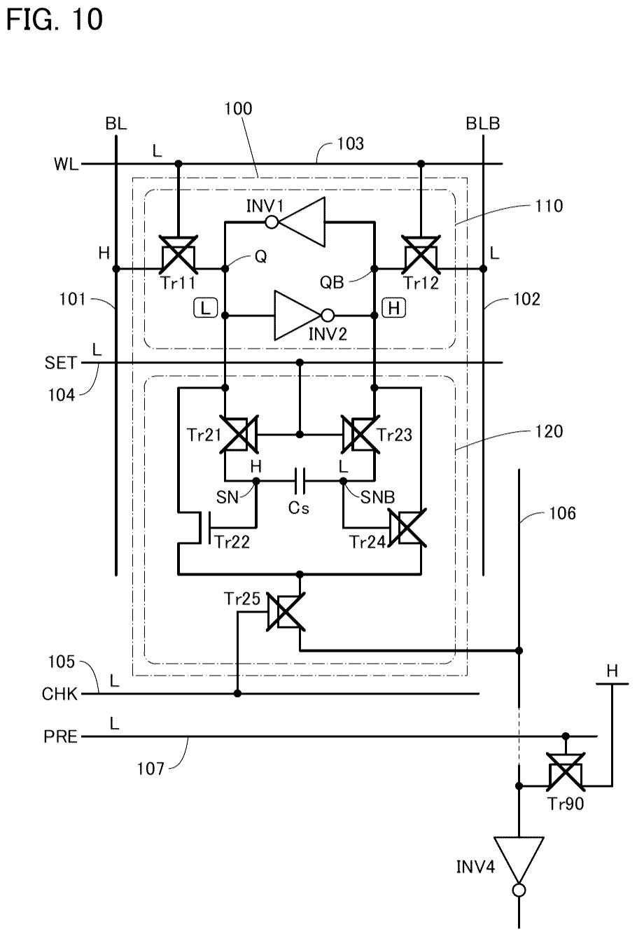

First, it is assumed here that a soft error occurs in Period T55 (see FIG. 5 and FIG. 10). For example, it is assumed that radiation enters the memory cell 100 and bit inversion occurs in the first memory circuit 110 including Si transistors. That is, in this embodiment, the logic value of the first data changes from “1” to “0”. Specifically, the potential of the node Q becomes the potential L, and the potential of the node QB becomes the potential H.

Since a soft error is less likely to occur in the second memory circuit 120 including OS transistors, bit inversion does not occur in the second memory circuit 120. The logic value of the second data remains “1”. Thus, in the memory cell 100 where a soft error has occurred, the logic values of data retained in the first memory circuit 110 and the second memory circuit 120 are different from each other.

Description of reading operation in the case where a soft error occurs in the memory cell 100 will be given with reference to Period T56 and Period T57. Immediately before the start of the reading operation (immediately before Period T56), the signal WL is at the potential L and the potential of the wiring 106 is the potential L. The wiring 101 and the wiring 102 are in a floating state.

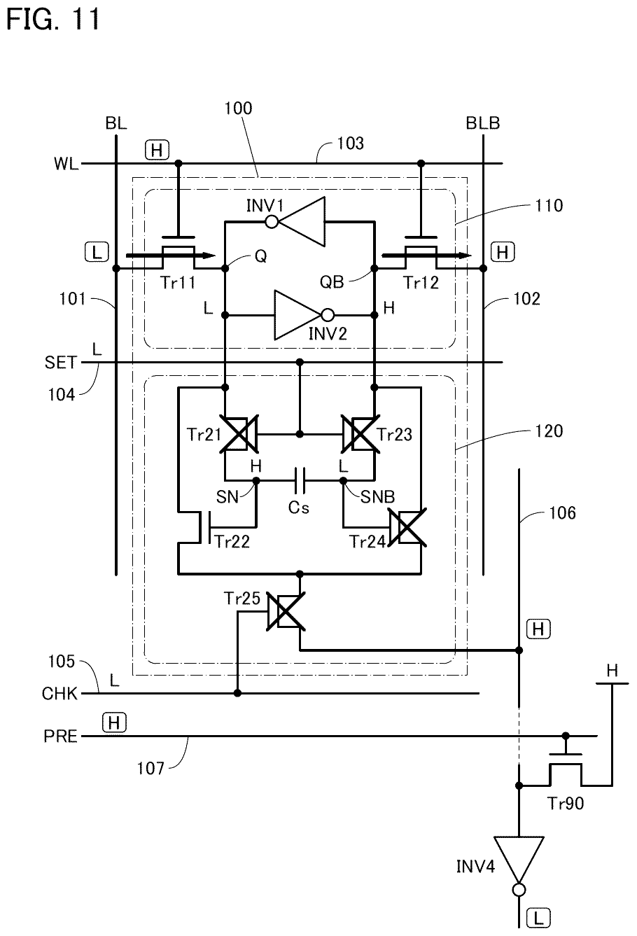

In Period T56, the signal WL and the signal PRE are set to the potential H (see FIG. 5 and FIG. 11). When the signal WL becomes the potential H, the output potential of the inverter circuit INVI is supplied to the wiring 101 and the output potential of the inverter circuit INV2 is supplied to the wiring 102 as in Period T53. Here, the potential L is supplied to the wiring 101, and the potential H is supplied to the wiring 102. The potential H is precharged to the wiring 106 as in Period T53. The output potential of the inverter circuit INV4 becomes the potential L.

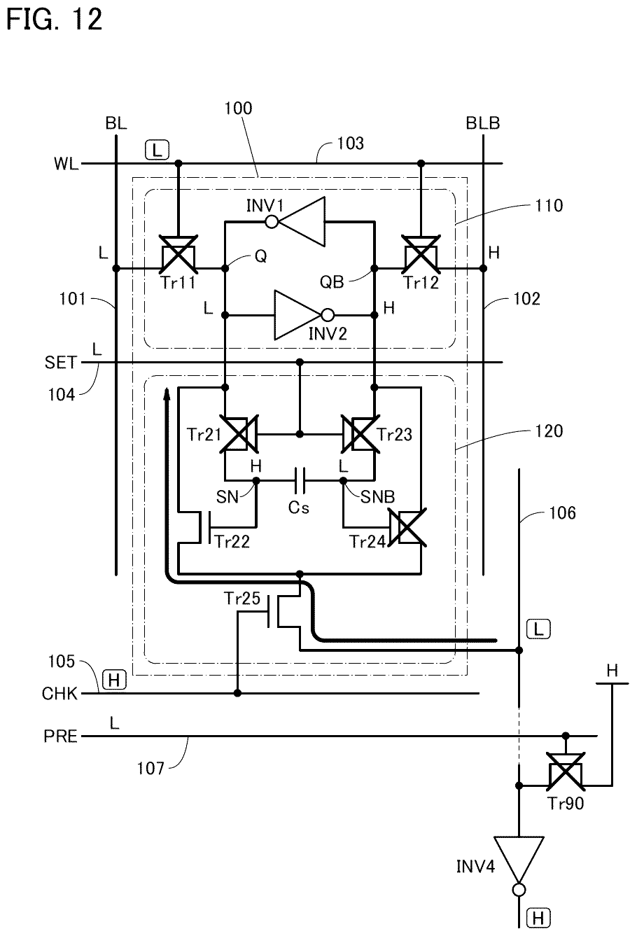

Next, in Period T57, the signal WL and the signal PRE are set to the potential L, and the signal CHK is set to the potential H (see FIG. 5 and FIG. 12). Note that in Period T57, the signal WL may remain at the potential H continuously from Period T56.

When the signal CHK becomes the potential H, the transistor Tr25 is turned on. At this time, since the potential of the node SN is the potential H, the transistor Tr22 is in an on state. The output potential of the inverter circuit INV1 is supplied to the wiring 106 through the transistor Tr22 and the transistor Tr25.

In Period T57, since the output potential of the inverter circuit INV1 is the potential L, the potential of the wiring 106 changes from the potential H to the potential L. Thus, the output of the inverter circuit INV4 changes from the potential L to the potential H. That is, the logic value of the first data changes from “0” to “1”.

When the logic values of the first data and the second data are different from each other, the potential L is output as the first signal from the memory cell 100 to the wiring 106. In addition, the potential H is output from the inverter circuit INV4.

As described above, the memory cell 100 of one embodiment of the present invention has a function of comparing the logic value of the first data and the logic value of the second data and outputting the comparison result as the first signal. Specifically, the memory cell of this embodiment has a function of outputting the potential L (the logic value of “1”) as the first signal when the logic value of the first data and the logic value of the second data are the same. The memory cell of this embodiment has a function of outputting the potential L (the logic value of “0”) as the first signal when the logic value of the first data and the logic value of the second data are different from each other.

More specifically, in this embodiment, when both the potential of the node Q and the potential of the node SN are the potential H or when both the potential of the node QB and the potential of the node SNB are the potential H, the potential H is output as the first signal from the memory cell 100. When the potential of the node Q is the potential L and the potential of the node SN is the potential H or when the potential of the node QB is the potential L and the potential of the node SNB is the potential H, the potential L is output as the first signal from the memory cell 100.

Note that when a p-channel transistor is used as each of the transistor Tr22 and the transistor Tr24, the potential of the first signal can be inverted. For example, with the use of a p-channel transistor as each of the transistor Tr22 and the transistor Tr24, when the logic value of the first data and the logic value of the second data are the same, the potential H (the logic value of “0”) can be output as the first signal. With the use of a p-channel transistor as each of the transistor Tr22 and the transistor Tr24, when the logic value of the first data and the logic value of the second data are different from each other, the potential H (the logic value of “1”) can be output as the first signal.

In this embodiment and the like, the output potential of the inverter circuit INV4 is referred to as an “error flag” in some cases. In this embodiment, the error flag is the potential H when a soft error occurs in the memory cell 100, and the error flag is the potential L when a soft error does not occur in the memory cell 100.

Alternatively, the first signal supplied from the memory cell 100 can be used as an “error flag”. In this case, in this embodiment, the error flag becomes the potential L when a soft error occurs in the memory cell 100, and the error flag becomes the potential H when a soft error does not occur in the memory cell 100.

In the case where the first signal output from the memory cell 100 is the potential L or the output potential of the inverter circuit INV4 is the potential H, occurrence of bit inversion due to a soft error in the memory cell 100 can be detected. Accordingly, in the case where the first signal is the potential L or the output potential of the inverter circuit INV4 is the potential H, true data can be obtained by inverting data read from the memory cell 100. For example, true data can also be obtained by performing a logical operation such as exclusive OR operation of read data and an error flag.

As described above, the memory cell 100 of one embodiment of the present invention can detect the presence or absence of a soft error for each bit (for each memory cell 100). Accordingly, a soft error can be corrected for each bit. When the memory cell 100 of one embodiment of the present invention is used for a memory device, a MBU soft error can be easily corrected. When the memory cell 100 of one embodiment of the present invention is used for a memory device, a memory device having higher reliability than an ECC memory can be achieved.

The structure described in this embodiment can be used in an appropriate combination with the structures described in the other embodiments.

### Embodiment 2

In this embodiment, a memory cell array 200 including the memory cells 100 of one embodiment of the present invention and a memory device 300 including and the memory cell array 200 are described.

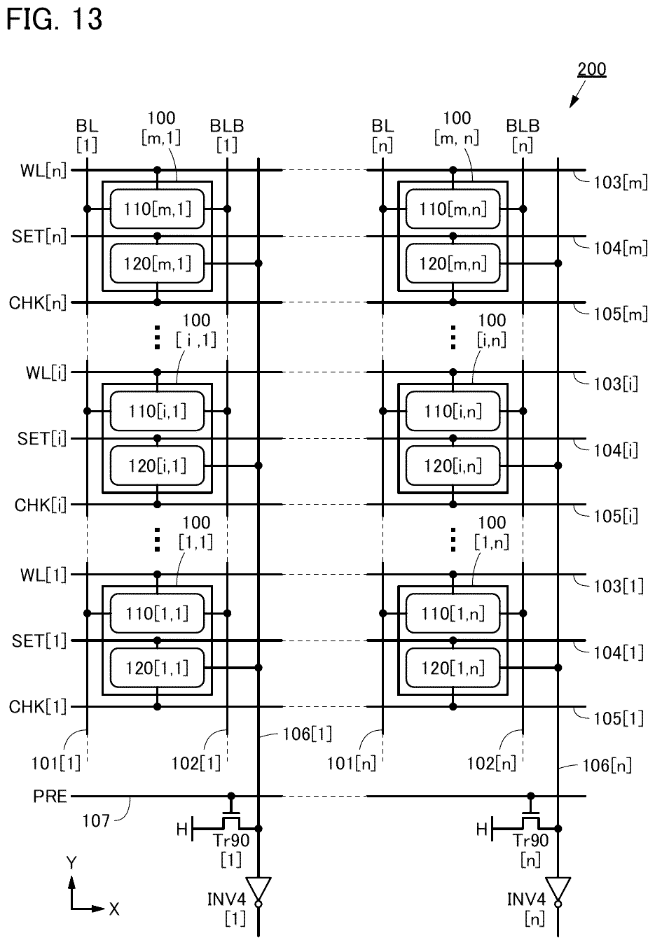

Memory Cell Array 200 FIG. 13 illustrates a structure example of the memory cell array 200 including a plurality of memory cells 100 arranged in a matrix of m rows and n columns (m and n are each an integer greater than or equal to 1). When the plurality of memory cell 100 are arranged in a matrix, a memory device with high memory capacity can be achieved.

In FIG. 13, the memory cell 100 in the first row and the first column is referred to as a memory cell 100[1,1], the memory cell 100 in the m-th row and the n-th column is referred to as a memory cell 100[m, n], the memory cell 100 in the i-th row and the first column (i represents a given row and is an integer greater than or equal to 1 and less than or equal to m) is referred to as a memory cell 100[i, 1], the memory cell 100 in the m-th row and the first column is referred to as a memory cell 100[m, 1], the memory cell 100 in the first row and the n-th column is referred to as a memory cell 100[1,n], and the memory cell 100 in the i-th row and the n-th column is referred to as a memory cell 100[i, n].

Note that the rows and the columns extend in directions orthogonal to each other. In this embodiment, the X direction (direction along the X-axis) is referred to as a “row” and the Y direction (direction along the Y-axis) is referred to as a “column”, but the X direction may be referred to as a “column” and the Y direction may be referred to as a “row”.

In this specification and the like, a given memory cell 100 among the plurality of memory cells 100 arranged in a matrix is referred to as “memory cell 100” or “memory cell 100[i, j]” (j represents a given column and is an integer greater than or equal to 1 and less than or equal to n) in some cases.

The first memory circuit 110 and the second memory circuit 120 included in each of the plurality of memory cells 100 arranged in a matrix are also referred to in a manner similar to that of the memory cells 100. For example, the first memory circuit 110 and the second memory circuit 120 included in the memory cell 100[1,1] are referred to as a first memory circuit 110[1,1] and a second memory circuit 120[1,1], respectively. For example, the first memory circuit 110 and the second memory circuit 120 included in the memory cell 100[m, n] are referred to as a first memory circuit 110[m, n] and a second memory circuit 120[m, n], respectively.

In FIG. 13, the wiring 103, the wiring 104, and the wiring 105 that are connected to the memory cells 100 arranged in the first row are referred to as a wiring 103[1], a wiring 104[1], and a wiring 105[1], respectively. The wiring 103, the wiring 104, and the wiring 105 that are connected to the memory cells 100 arranged in the i-th row are referred to as a wiring 103[i], a wiring 104[i], and a wiring 105[i], respectively. The wiring 103, the wiring 104, and the wiring 105 that are connected to the memory cells 100 arranged in the m-th row are referred to as a wiring 103[m], a wiring 104[m], and a wiring 105[m].

In FIG. 13, the signal WL supplied to the wiring 103[1] is referred to as a signal WL[1], the signal SET supplied to the wiring 104[1] is referred to as a signal SET[1], and the signal CHK supplied to the wiring 105[1] is referred to as a signal CHK[1]. Wirings and signals in the m-th row and wirings and signals in the i-th row are referred to in the similar manner.

In FIG. 13, the wiring 106 connected to the memory cells 100 arranged in the first column is referred to as a wiring 106[1], and the wiring 106 connected to the memory cells 100 arranged in the n-th column is referred to as a wiring 106[n]. The transistor Tr90 and the inverter circuit INV4 that are connected to the wiring 106[1] are referred to as a transistor Tr 90[1] and an inverter circuit INV4[1], respectively, and the transistor Tr90 and the inverter circuit INV4 that are connected to the wiring 106[n] are referred to as a transistor Tr 90[n] and an inverter circuit INV4[n], respectively.

### Memory Device 300

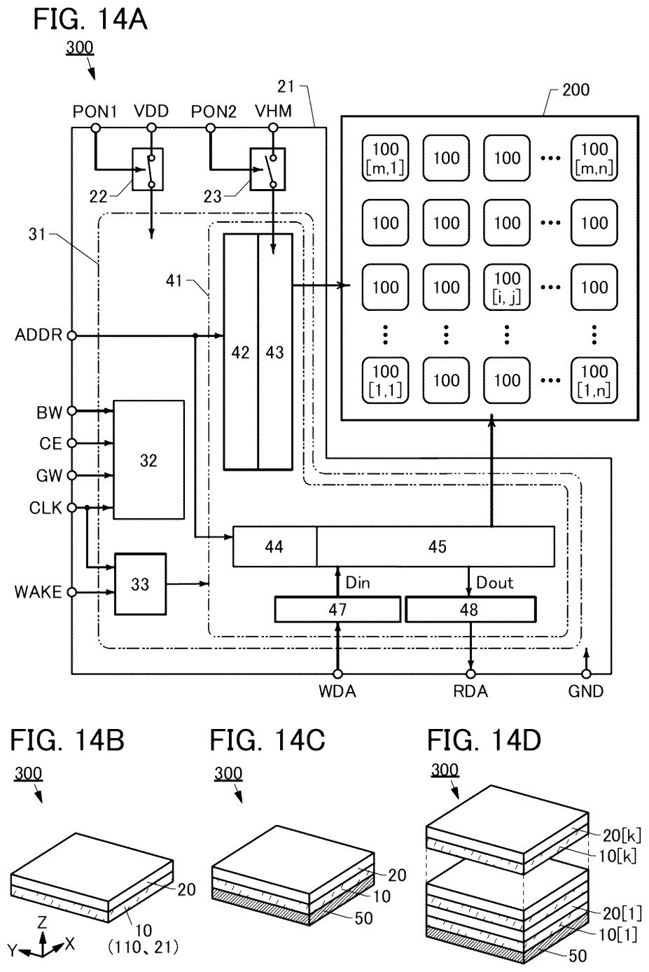

FIG. 14A is a block diagram illustrating a structure example of the memory device 300 including memory cells 100 of one embodiment of the present invention. The memory device 300 illustrated in FIG. 14A includes a driver circuit 21 and the memory cell array 200.

The driver circuit 21 includes a PSW 22 (power switch), a PSW 23, and a peripheral circuit 31. The peripheral circuit 31 includes a peripheral circuit 41, a control circuit 32 (Control Circuit), and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PONI and the signal PON2 are power gating control signals. The signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating voltage. The signal WAKE has a function of controlling the input of the signal CLK to the voltage generation circuit 33. For example, when a signal at the potential H is supplied as the signal WAKE, the signal CLK is input to the voltage generation circuit 33, and the voltage generation circuit 33 generates voltage.

The peripheral circuit 41 is a circuit for writing and reading data to/from the memory cells 100. The peripheral circuit 41 includes a row decoder 42 (Row Decoder), a column decoder 44 (Column Decoder), a row driver 43 (Row Driver), a column driver 45 (Column Driver), an input circuit 47 (Input Cir.), and an output circuit 48 (Output Cir.).

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring specified by the row decoder 42. The column driver 45 has a function of writing data to the memory cells 100, a function of reading data from the memory cells 100, a function of retaining the read data, and the like.

The input circuit 47 has a function of retaining the signal WDA. Data retained by the input circuit 47 is output to the column driver 45. Data output from the input circuit 47 is data (Din) to be written to the memory cells 100. Data (Dout) read from the memory cells 100 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 300, a high power supply potential is VDD and a low power supply potential is GND (a ground potential). In addition, VHM is a high power supply potential used to set the word line to the potential H and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 14A but can be more than one. In that case, a power switch is provided for each power domain.

As illustrated in FIG. 14B, the first memory circuit 110 and the driver circuit 21 may be provided in the layer 10. When the first memory circuit 110 and the driver circuit 21 are provided in the layer 10, the first memory circuit 110 and the driver circuit 21 can be formed at the same time, so that the productivity of the memory device 300 can be increased.

As illustrated in FIG. 14C, the driver circuit 21 may be provided in a layer 50, and the layer 10 and the layer 20 may be provided to overlap with the layer 50. Like the layer 10, a single crystal semiconductor substrate, an SOI substrate, or the like can be used for the layer 10. The layer 50 and the layer 10 can be connected to each other by a through electrode technique such as a TSV (Through Silicon Via) or a bonding technique such as a Cu-Cu direct bonding technique. When the layer 10 and the layer 50 including the driver circuit 21 are separately formed, the operation of the driver circuit 21 included in the layer 50 can be confirmed before the connection of the layer 50 and the layer 10. Consequently, the manufacturing yield of the memory device 300 can be improved because only the non-defective layer 50 can be connected to the layer 10.

As illustrated in FIG. 14D, the layer 10 and the layer 20 included in the memory cell array 200 may be repeatedly provided to overlap with each other over the layer 50 including the driver circuit 21. FIG. 14D illustrates an example in which the k layers 10 (k is an integer greater than or equal to 2) and the k layers 20 are provided to overlap with each other over the layer 50. The layer 10 and the layer 20 provided over the layer 50 as a first layer are referred to as a layer 10[1] and a layer 20[1], respectively, and the layer 10 and the layer 20 provided over the layer 50 as a k-th layer are referred to as a layer 10[k] and a layer 20[k], respectively.

When the layer 10 and the layer 20 included in the memory cell array 200 are provided to overlap with the layer 50 including the driver circuit 21, a signal transmission distance between the driver circuit 21 and the memory cell array 200 can be shortened. Accordingly, the parasitic resistance and the parasitic capacitance between the driver circuit 21 and the memory cell array 200 are reduced, so that power consumption and signal delays can be reduced. In addition, the memory device 300 can be downsized. Moreover, the memory capacity per unit area can be increased.

The structure described in this embodiment can be used in an appropriate combination with the structures described in the other embodiments.

### Embodiment 3

In this embodiment, a memory system 400 including the memory device 300 is described.

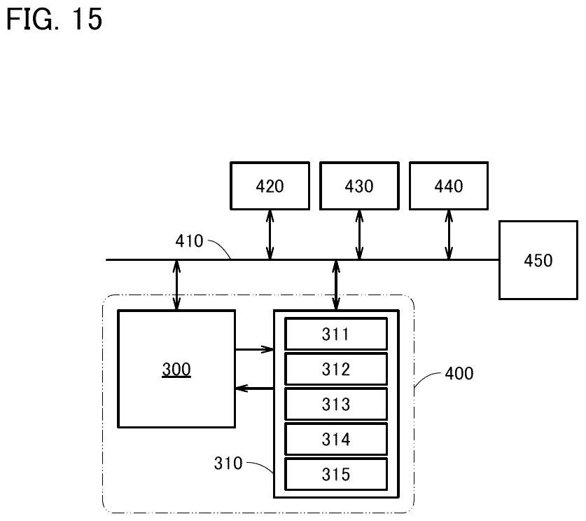

memory System 400
FIG. 15 is a block diagram of the memory system 400. The memory system 400 includes the memory device 300 and a control device 310. The control device 310 includes an arithmetic device 311, an input/output device 312, a timer device 313, a setting register 314, and an error flag register 315. The memory device 300 and the control device 310 are each connected to a CPU (Central Processing Unit) 450 through a bus line 410. The CPU 450 has a function of supplying control signals for the memory device 300 and the control device 310, data to be written to the memory device 300, and a writing destination address to the memory system 400 through the bus line 410. Note that the memory system 400 can be connected not only to the CPU 450, but also to a communication device 420, an external memory device 430, a GPU 440, and the like through the bus line 410.

The memory device 300 has a function of supplying an address and an error flag of the memory cell 100 in which a soft error has occurred to the control device 310 not through the bus line 410. The control device 310 has a function of supplying a control signal for the second memory circuit 120 of the memory cell 100 included in the memory device 300.

The arithmetic device 311 included in the control device 310 has a function of inverting data at an address where a soft error has occurred. Input and output of data to/from the control device 310 are performed through the input/output device 312. The timer device 313 has a function of determining an execution interval of memory scrubbing, for example. The setting register 314 has a function of retaining a control signal such as an operation parameter of the control device 310 that is supplied through the bus line 410. The error flag register 315 has a function of retaining an error flag and an address supplied from the memory device 300.

Data to be written to the memory device 300 is supplied to the memory device 300 through the bus line 410. Data retained in the memory device 300 is read through the bus line 410.

An error flag output from the memory cell 100 is supplied to the control device 310 not through the bus line 410. Note that an error flag output from the memory cell 100 can also be supplied to the control device 310 through the bus line 410.

Control signals (the signal SET and the signal CHK) for the second memory circuit 120 are supplied from the control device 310 to the memory device 300 not through the bus line 410. Note that control signals for the second memory circuit 120 can also be supplied to the memory device 300 through the bus line 410.

Note that the CPU 450 may perform some or all of the functions of the control device 310. In this case, control of the memory device 300 is performed through the bus line 410; thus the operation of the memory system 400 is sometimes slowed. Meanwhile, the area occupied by the memory system 400 can be reduced.

### Operation Example

Next, the operation of the memory system 400 is described.

### Data Writing Operation

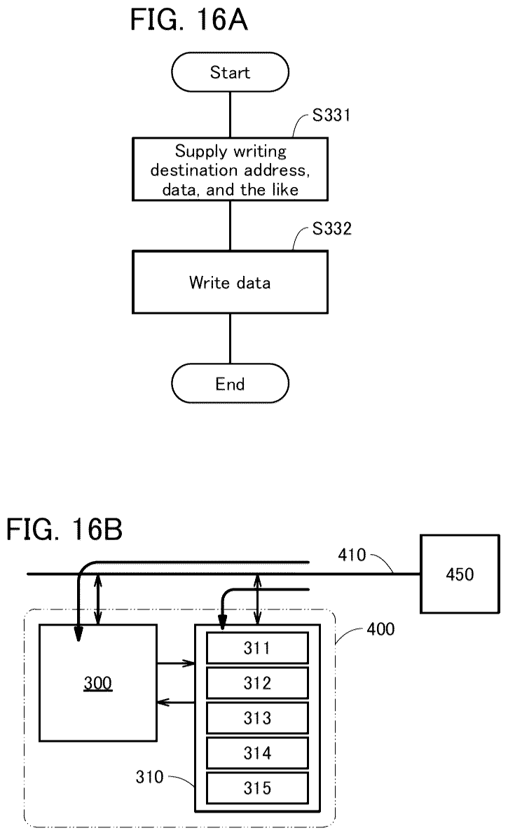

Operation of writing data to the memory device 300 included in the memory system 400 is described. FIG. 16A is a flow chart showing data writing operation. FIG. 16B is a block diagram illustrating an operation state of the memory system 400.

In Step S331, the CPU 450 supplies, to the memory device 300 through the bus line 410, writing destination address data and data to be written. The CPU 450 supplies writing destination address data to the control device 310.

In Step S332, the memory device 300 writes data to the address specified by the CPU 450. The control device 310 supplies a control signal for the second memory circuit 120 in the address specified by the CPU 450. As described in Embodiment 1, the same data is written to the first memory circuit 110 and the second memory circuit 120 in the memory cell 100 subjected to writing. In this manner, data can be written to the memory device 300.

### Reading Operation 1

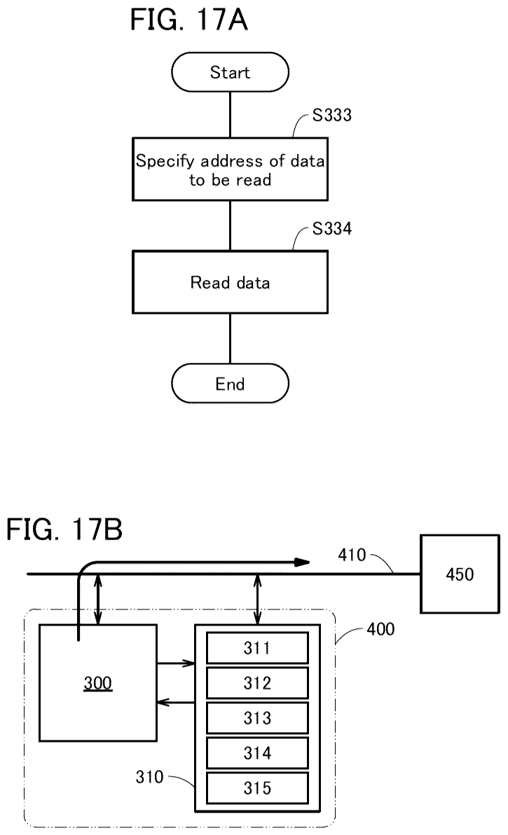

Operation of reading data from the memory device 300 included in the memory system 400 is described. FIG. 17A is a flow chart showing reading operation 1. FIG. 17B is a block diagram illustrating an operation state of the memory system 400.

The reading operation 1 is performed in the case where memory scrubbing of the memory system 400, which is described later, is executed relatively frequently.

In Step S333, the CPU 450 specifies data of an address where data to be read from the memory device 300 through the bus line 410 is retained.

In Step S334, the memory device 300 supplies data retained in the address specified by the CPU 450 to the CPU 450 and the like through the bus line 410. In other words, the CPU 450 reads data retained in the specified address from the memory device 300.

### Reading Operation 2

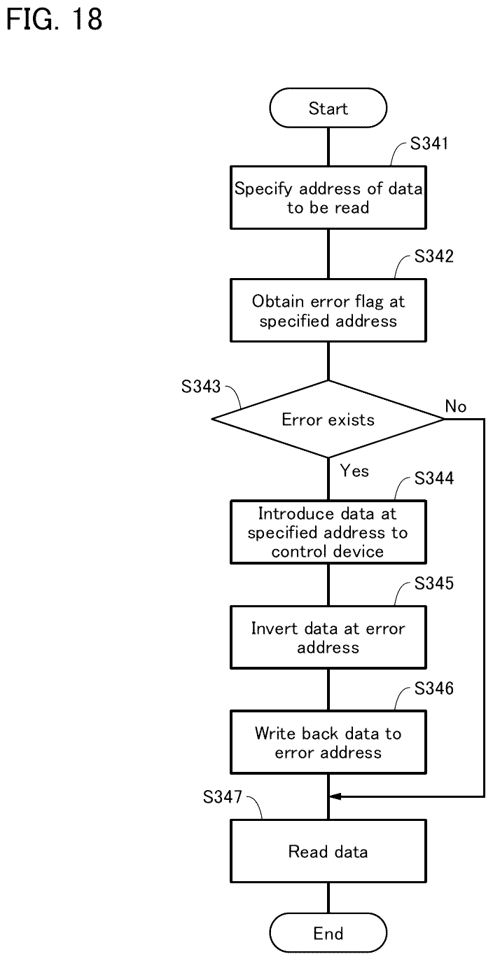

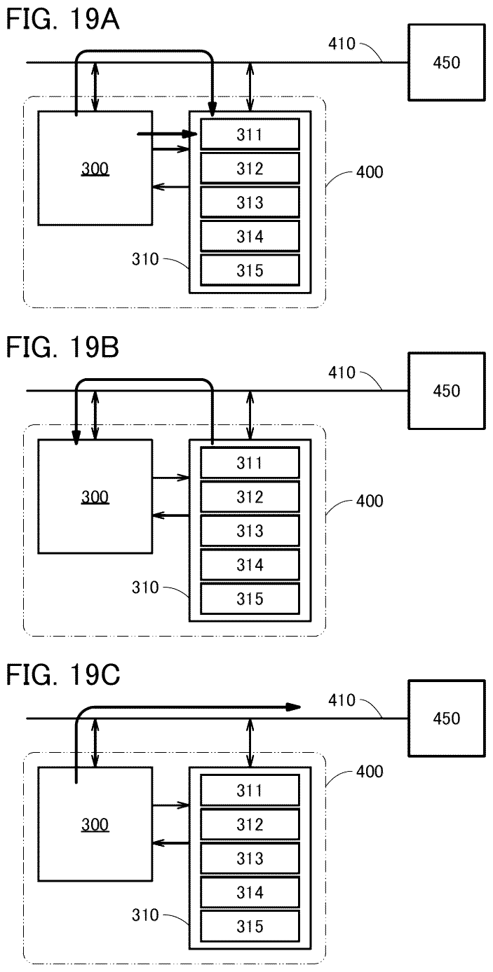

Reading operation 2 which includes different operation from the reading operation 1 is described. FIG. 18 is a flow chart showing the reading operation 2. FIG. 19A to FIG. 19C are block diagrams each illustrating an operation state of the memory system 400.

The reading operation 2 is performed in the case where memory scrubbing of the memory system 400, which is described later, is executed relatively less frequently or memory scrubbing is not executed.

In Step S341, the CPU 450 specifies data of an address where data to be read from the memory device 300 and the control device 310 through the bus line 410 is retained.

In Step S342, the control device 310 supplies the signal CHK to the memory cell 100 at the specified address in the memory device 300, and obtains an error flag of the memory cell 100.

In Step S343, whether an error exists in the memory cell 100 at the specified address or not is determined.

In the case where an error exists in the data at the specified address, Step S344 is executed. In Step S344, the data at the address is introduced to the control device 310 through the bus line 410 (see FIG. 19A).

In Step S345, the data at the error address is inverted to be corrected data.

In Step S346, the corrected data is written back to the error address in the memory device 300 (see FIG. 19B).

In the case where it is determined that no error exists in the memory cell 100 at the specified address in Step S343, Step S344 to Step S346 are not performed and the process moves to Step S347.

In Step S347, the memory device 300 supplies data retained in the address specified by the CPU 450 to the CPU 450 and the like through the bus line 410. In other words, the CPU 450 reads data retained in the specified address from the memory device 300 through the bus line 410 (see FIG. 19C).

The reading operation 2 takes more time to read data than the reading operation 1, but can increase the reliability of read data.

### Memory Scrubbing Operation

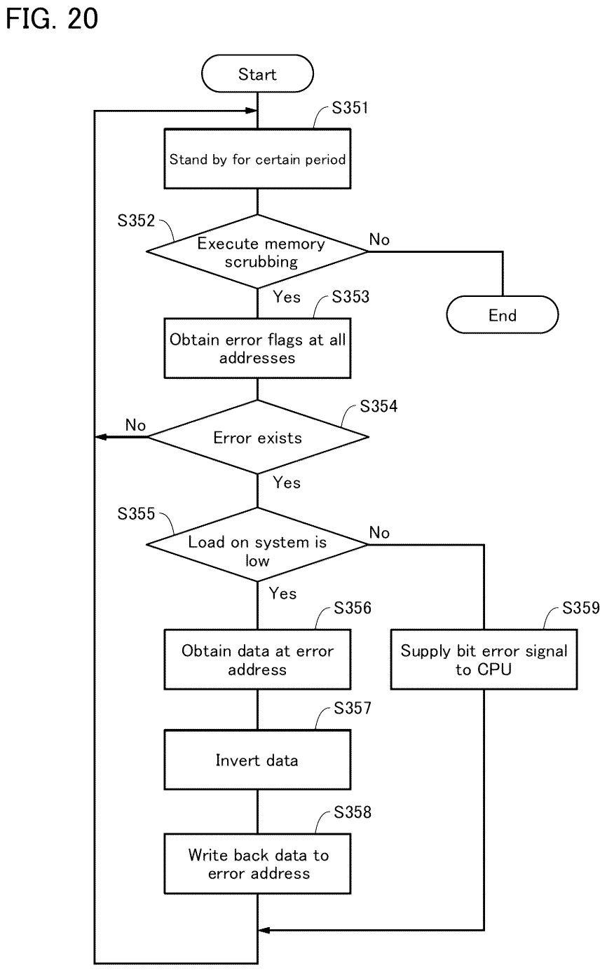

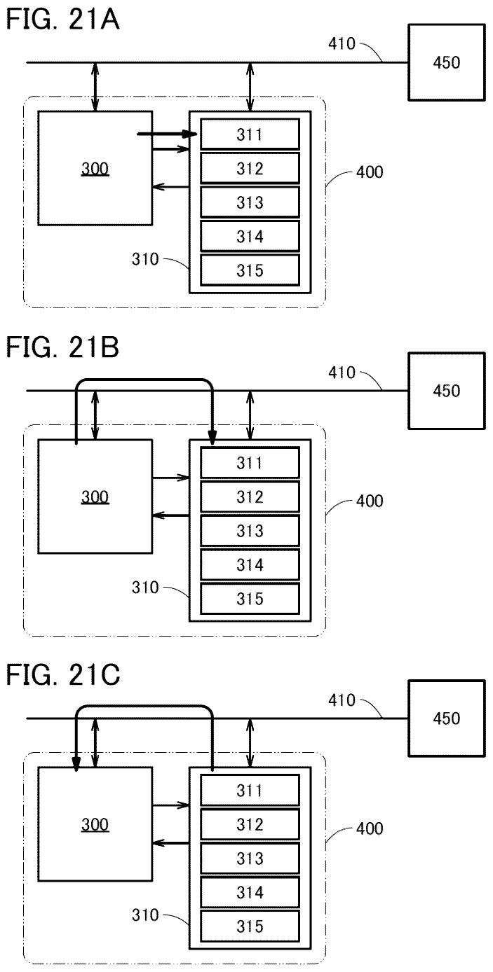

Memory scrubbing operation in the memory system 400 is described. FIG. 20 is a flow chart showing memory scrubbing operation in the memory system 400. FIG. 21A to FIG. 21C are block diagrams each illustrating an operation state of the memory system 400.

In Step S351, the memory system 400 stands by for a certain period. The standby period in Step S351 determines the execution frequency of memory scrubbing.

In Step S352, whether memory scrubbing is executed or not is determined. In the case where the instruction to execute memory scrubbing has been supplied from the CPU 450, or the instruction to stop memory scrubbing has not been supplied from the CPU 450 after supply of the instruction to execute memory scrubbing, memory scrubbing is executed. In the case where the instruction to stop memory scrubbing has been supplied from the CPU 450, or the instruction to execute memory scrubbing has not been supplied from the CPU 450 after supply of the instruction to stop memory scrubbing, memory scrubbing is not executed.

In Step S353, the control device 310 supplies the signal CHK to each of the memory cells 100 at all addresses included in the memory device 300, and obtains an error flag from each of all the addresses (see FIG. 21A). The obtained error flag is retained in the error flag register 315 together with the data of the address of the corresponding memory cell 100.

In Step S354, whether an error exists in at least part of the memory cells 100 at all addresses or not is determined.

In the case where no error exists, the process moves to Step S351. In the case where an error exists, whether the load on the whole system including the CPU 450 is high or low is determined in Step S355. Here, “the load on the whole system including the CPU 450 is high” means a state where the bus line 410 is used in other processing, for example.

In the case where the load on the whole system including the CPU 450 is high, the process moves to Step S359. In Step S359, a bit error signal indicating that an error exists in data retained in the memory device 300 is supplied to the CPU 450. After that, the process moves to Step S351.

In the case where the load on the whole system including the CPU 450 is low, the process moves to Step S356. In Step S356, the control device 310 obtains data at the error address from the memory device 300 through the bus line 410 on the basis of data of the address retained in the error flag register 315 (see FIG. 21B).

In Step S357, the data at the error address is inverted to be corrected data.

In Step S358, the corrected data is written back to the error address in the memory device 300 (see FIG. 21C). After that, the process moves to Step S351. In the case where Step S359 has been previously performed and a bit error signal has been supplied to the CPU 450, a signal indicating that the bit error has been solved is supplied to the CPU 450 after the corrected data is written back to the memory cell 100.

By performing memory scrubbing operation at a constant frequency, the amount of error data can be reduced. The memory device 300 including the memory cells 100 of one embodiment of the present invention can correct data with MBU and thus can reduce the execution frequency of memory scrubbing operation. Thus, the power consumption of the memory device 300 can be reduced.

In addition, memory scrubbing operation enables data reading by the reading operation 1 not by the reading operation 2, so that high-speed data reading can be achieved.

The memory device 300 or the memory system 400 of one embodiment of the present invention may be used for an ECC memory. When the memory device 300 or the memory system 400 of one embodiment of the present invention is used for an ECC memory, the soft-error tolerance can be further increased. That is, the reliability of the semiconductor device can be further increased.

The structure described in this embodiment can be used in an appropriate combination with the structures described in the other embodiments.

### Embodiment 4

In this embodiment, planar structure examples and cross-sectional structure examples of the second memory circuit 120 provided in the layer 20 are described. Note that the second memory circuit 120 is a kind of semiconductor device.

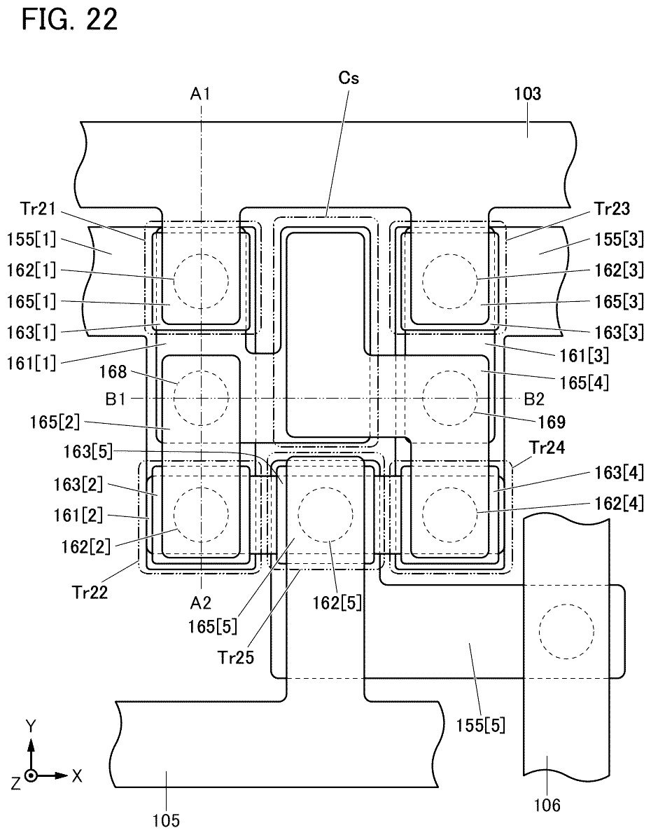

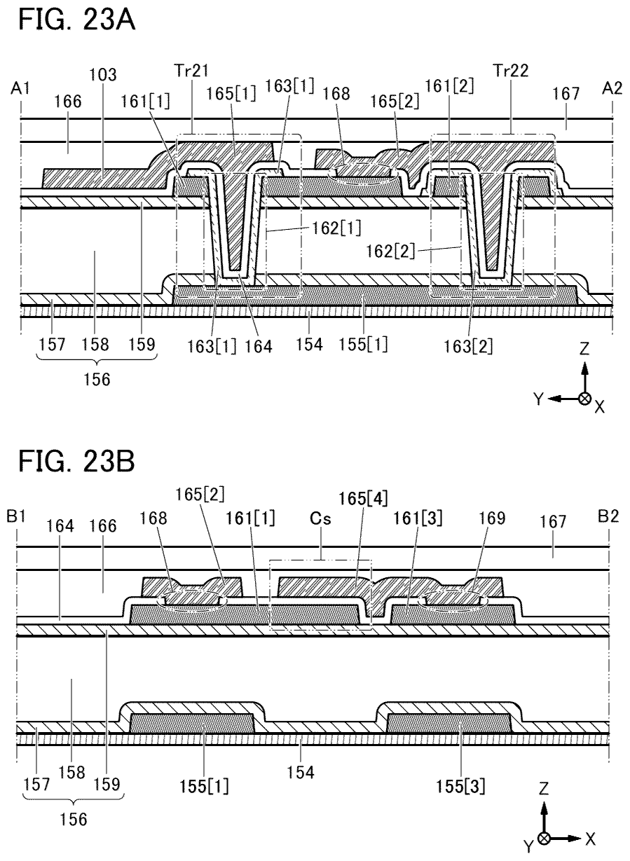

FIG. 22 is a plan view of the second memory circuit 120, which is seen from the Z direction. FIG. 23A is a cross-sectional view of a portion indicated by the dashed-dotted line A1-A2 in FIG. 22, which is seen from the X direction. FIG. 23B is a cross-sectional view of a portion indicated by the dashed-dotted line A3-A4 in FIG. 22, which is seen from the Y direction. Note that for clarity of the drawing, some components such as insulating layers are omitted in the plan view of FIG. 22.

In FIG. 22, FIG. 23A, and FIG. 23B, the second memory circuit 120, which is a kind of semiconductor device, includes an insulating layer 154 and includes a conductive layer 155 (a conductive layer 155[1], a conductive layer 155[3], and a conductive layer 155[5]) over the insulating layer 154. The second memory circuit 120 includes an insulating layer 157 over the insulating layer 154 and the conductive layer 155, an insulating layer 158 over the insulating layer 157, and an insulating layer 159 over the insulating layer 158. In this specification and the like, the insulating layer 157, the insulating layer 158, and the insulating layer 159 are collectively referred to as an insulating layer 156 or a spacer layer in some cases. A conductive layer 161 (a conductive layer 161[1] to a conductive layer 161[3]) and a conductive layer 106 (not illustrated in FIG. 23A and FIG. 23B) are provided over the insulating layer 159.

In FIG. 22 and FIG. 23A, an opening 162[1] is provided in the conductive layer 161[1], the insulating layer 159, the insulating layer 158, and the insulating layer 157 in a region overlapping with part of the conductive layer 155[1]. In other region overlapping with part of the conductive layer 155[1], an opening 162[2] is provided in the insulating layer 159, the insulating layer 158, and the insulating layer 157. In addition, the semiconductor layer 163[1] covering the opening 162[1] and the semiconductor layer 163[2] covering the opening 162[2] are provided.

The semiconductor layer 163[1] includes a region overlapping with the bottom portion of the opening 162[1] and a region overlapping with the side surface of the opening 162[1]. That is, the semiconductor layer 163[1] includes a region in contact with the insulating layer 156. The semiconductor layer 163[1] includes a region in contact with the conductive layer 155[1] and a region in contact with the conductive layer 161[1]. The semiconductor layer 163[1] may include a region extending beyond an end portion of the conductive layer 161[1].

The semiconductor layer 163[2] includes a region overlapping with the bottom portion of the opening 162[2] and a region overlapping with the side surface of the opening 162[2]. That is, the semiconductor layer 163[2] includes a region in contact with the insulating layer 156. The semiconductor layer 163[2] includes a region in contact with the conductive layer 155[1] and a region in contact with the conductive layer 161[2]. The semiconductor layer 163[2] may include a region extending beyond an end portion of the conductive layer 161[2].

In FIG. 23A, an insulating layer 164 is provided over the insulating layer 159, the conductive layer 161[1], the semiconductor layer 163[1], the conductive layer 161[2], and the semiconductor layer 163[2]. A conductive layer 165[1] and a conductive layer 165[2] are provided over the insulating layer 164. The conductive layer 165[1] includes a region overlapping with the semiconductor layer 163[1]. The conductive layer 165[2] includes a region overlapping with the semiconductor layer 163[2].

In FIG. 23B, a conductive layer 165[4] is provided over the insulating layer 164. The conductive layer 165[4] includes a region overlapping with part of the conductive layer 161[1] and a region overlapping with part of the conductive layer 161[3].

In FIG. 23A, the insulating layer 164 and the conductive layer 165[1] include a region overlapping with the opening 162[1]. The insulating layer 164 and the conductive layer 165[2] include a region overlapping with the opening 162[2]. In the opening 162[1], the semiconductor layer 163[1] includes a region overlapping with the conductive layer 161[1] with the insulating layer 164 therebetween and a region overlapping with the side surface of the opening 162[1] (side surface of the insulating layer 156). In the opening 162[2], the semiconductor layer 163[2] includes a region overlapping with the conductive layer 161[2] with the insulating layer 164 therebetween and a region overlapping with the side surface of the opening 162[2] (other side surface of the insulating layer 156).

Here, the thickness of the semiconductor layer 163 is preferably larger than or equal to 1 nm, larger than or equal to 3 nm, or larger than or equal to 5 nm and smaller than or equal to 20 nm, smaller than or equal to 15 nm, smaller than or equal to 12 nm, or smaller than or equal to 10 nm. The thickness of the insulating layer 164 is preferably larger than or equal to 0.5 nm and smaller than or equal to 15 nm, further preferably larger than or equal to 0.5 nm and smaller than or equal to 12 nm, still further preferably larger than or equal to 0.5 nm and smaller than or equal to 10 nm. At least part of the insulating layer 164 includes a region with the above-described thickness.

An opening 168 overlapping with the conductive layer 161[1] is provided in part of the insulating layer 164. The conductive layer 161[1] and the conductive layer 165[2] are connected to each other in the opening 168.

In FIG. 23A, an insulating layer 167 is provided over the insulating layer 164 and an insulating layer 166. Note that the top surface of the insulating layer 166 is preferably flat. Alternatively, the positions (positions in the Z direction) of the top surfaces of the insulating layer 166, the conductive layer 165[1], and the conductive layer 165[2] may be aligned or substantially aligned with each other. For example, the planarity of the top surface of the insulating layer 166 can be improved by chemical mechanical polishing (CMP) treatment or the like. The positions of the top surfaces of the insulating layer 166, the conductive layer 165[1], and the conductive layer 165[2] can be aligned or substantially aligned with each other by CMP treatment. The unevenness of a sample surface is reduced by performing CMP treatment, which increases the coverage with insulating layers and conductive layers that are to be formed later. In FIG. 23A, the insulating layer 167 is provided over the conductive layer 165[1], the conductive layer 165[2], and the insulating layer 166.

In FIG. 23B, an opening 169 overlapping with the conductive layer 161[3] is provided in part of the insulating layer 164. The conductive layer 161[3] and the conductive layer 165[4] are connected to each other in the opening 169. A region where the conductive layer 161[1] and the conductive layer 165[4] overlap with each other with the insulating layer 164 therebetween functions as a capacitor element Cs. Thus, part of the conductive layer 161[1] functions as one electrode of the capacitor element Cs, and part of the conductive layer 165[4] functions as the other electrode of the capacitor element Cs. In FIG. 23B, the insulating layer 167 is provided over the conductive layer 165[2], the conductive layer 165[4], and the insulating layer 166.

Note that the conductive layer 161[1] and the conductive layer 165[2] function as the node SN of the memory cell 100. The conductive layer 161[3] and the conductive layer 165[4] function as the node SNB of the memory cell 100.

In FIG. 22 and FIG. 23A, a region overlapping with the opening 162[1] functions as the transistor Tr21. A region overlapping with the opening 162[2] functions as the transistor Tr22. Thus, part of the conductive layer 161[1] functions as the one of the source electrode and the drain electrode of the transistor Tr21. Part of the conductive layer 155[1] functions as the other of the source electrode and the drain electrode of the transistor Tr21. For example, in the case where part of the conductive layer 161[1] functions as the drain electrode of the transistor Tr21, part of the conductive layer 155[1] functions as the source electrode of the transistor Tr21. Note that the conductive layer 155[1] functions as the node Q of the memory cell 100.

The semiconductor layer 163[1] functions as a semiconductor layer of the transistor Tr21 where a channel is formed (a semiconductor layer including a channel formation region); part of the insulating layer 164 functions as a gate insulating layer; and the conductive layer 165[1] functions as a gate electrode.

Part of the conductive layer 161[2] functions as the one of the source electrode and the drain electrode of the transistor Tr22. Other part of the conductive layer 155[1] functions as the other of the source electrode and the drain electrode of the transistor Tr22. For example, in the case where part of the conductive layer 161[2] functions as the drain electrode of the transistor Tr22, other part of the conductive layer 155[1] functions as the source electrode of the transistor Tr22. The semiconductor the layer 163[2] functions as a semiconductor layer of the transistor Tr22 where a channel is formed; other part of the insulating layer 164 functions as a gate insulating layer; and the conductive layer 165[1] functions as a gate electrode.

In FIG. 22, the transistor Tr23, the transistor Tr24, and the transistor Tr25 each have a structure similar to those of the transistor Tr21 and the transistor Tr22. The structure of the transistor Tr23 can be understood by replacing the conductive layer 155[1], the conductive layer 161[1], the opening 162[1], and the semiconductor layer 163[1] in the above description with the conductive layer 155[3], the conductive layer 161[3], the opening 162[3], and the semiconductor layer 163[3], respectively. Note that the conductive layer 155[3] functions as the node QB of the memory cell 100.

The structure of the transistor Tr24 can be understood by replacing the conductive layer 155[1], the conductive layer 161[1], the opening 162[2], and the semiconductor layer 163[2] in the above description with the conductive layer 155[3], the conductive layer 161[2], the opening 162[4], and the semiconductor layer 163[4], respectively. The structure of the transistor Tr25 can be understood by replacing the conductive layer 155[1], the conductive layer 161[1], the opening 162[2], and the semiconductor layer 163[1] in the above description with the conductive layer 155[5], the conductive layer 161[2], the opening 162[5], and the semiconductor layer 163[5], respectively. The conductive layer 155[5] is connected to the wiring 106.

The conductive layer 165[1] is connected to the wiring 103. FIG. 22 illustrates an example in which part of the wiring 103 functions as the conductive layer 165[1]. The conductive layer 165[3] provided in the same layer as the conductive layer 165[1] is also connected to the wiring 103. FIG. 22 illustrates an example in which part of the wiring 103 functions as the conductive layer 165[3]. The conductive layer 165[5] provided in the same layer as the conductive layer 165[1] is connected to the wiring 105. FIG. 22 illustrates an example in which part of the wiring 105 functions as the conductive layer 165[5].

The transistor Tr21 to the transistor Tr25 illustrated in FIG. 22, FIG. 23A, and FIG. 23B are each a transistor in which the source electrode and the drain electrode are placed in the Z direction. That is, the sources and the drains of the transistor Tr21 to the transistor Tr25 are placed at different levels. In other words, the sources and the drains of the transistor Tr21 to the transistor Tr25 are placed at different positions in the Z direction. Such a transistor is also referred to as a “vertical-channel transistor”, a “vertical transistor”, or a “VFET (Vertical Field Effect Transistor)”.

The area occupied by the vertical transistor can be smaller than that occupied by a conventional transistor in which the channel formation region, the source region, and the drain region are provided separately on the X-Y plane. Thus, when the vertical-channel transistor is used in a semiconductor device, the area occupied by the semiconductor device can be reduced. When the vertical-channel transistor is used in a semiconductor device, high integration of the semiconductor device can be achieved. It is also possible to increase the memory capacity per unit area of a memory device including the semiconductor device.

The channel length of a conventional transistor is determined by the light exposure limit of photolithography. The channel length of the vertical-channel transistor of one embodiment of the present invention can be determined by the thickness of the insulating layer 156 or the insulating layer 158. Thus, the transistor can have an extremely small channel length smaller than or equal to the light exposure limit of photolithography (e.g., smaller than or equal to 60 nm, smaller than or equal to 50 nm, smaller than or equal to 40 nm, smaller than or equal to 30 nm, smaller than or equal to 20 nm, or smaller than or equal to 10 nm, and larger than or equal to 1 nm, or larger than or equal to 5 nm). Accordingly, the transistor Tr21 to the transistor Tr25 can each have a higher on-state current and improved frequency characteristics. The use of a vertical-channel transistor can provide a semiconductor device with high operation speed.

Note that although the vertical-channel transistor is described as an example of the transistor in this embodiment, one embodiment of the present invention is not limited thereto. For example, a transistor having any of a variety of structures such as a planar type, a staggered type, a FIN-type, a TRI-GATE type, a top-gate type, a bottom-gate type, and a dual-gate type (a structure in which gates are placed on the opposite sides with a channel formation region therebetween (placed above and below the channel formation region, for example) can be used for the semiconductor device of one embodiment of the present invention.

### Constituent Material

An example of a material that can be used for the second memory circuit 120, which is a kind of semiconductor device, is described.

### Substrate

In the case where the semiconductor device is provided over a substrate, there is no particular limitation on a material used for the substrate. The material is determined in accordance with the purpose in consideration of whether it has a light-transmitting property, heat resistance high enough to withstand heat treatment, or the like. For example, an insulator substrate, a semiconductor substrate, or a conductor substrate is used. As the insulator substrate, for example, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used. Alternatively, a semiconductor substrate, a flexible substrate, a resin substrate, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, gallium oxide, or the like as a material. Another example is a semiconductor substrate having an insulator region in the semiconductor substrate described above, e.g., an SOI (Silicon On Insulator) substrate. The semiconductor substrate may be a single crystal semiconductor or a poly crystalline semiconductor.

Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductive layer or a semiconductor, a semiconductor substrate provided with a conductive layer or an insulating layer, and a conductor substrate provided with a semiconductor layer or an insulating layer.

For the materials of the flexible substrate, the resin substrate, or the like, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, poly amide imide, polyurethane, polyvinyl chloride, polyvinylidene chloride, polypropylene, polytetrafluoroethylene (PTFE), an ABS resin, or cellulose nanofiber can be used, for example.

When the above-described material is used for the substrate, a lightweight semiconductor device can be provided. Furthermore, when the above-described material is used for the substrate, a shock-resistant semiconductor device can be provided. Moreover, when the above-described material is used for the substrate, a semiconductor device that is less likely to be broken can be provided.

Alternatively, these substrates provided with elements may be used. Examples of the element provided for the substrate include a capacitor element, a resistor element, a switching element, a light-emitting element, and a memory element.

### Insulating Layer

An insulating oxide, an insulating nitride, an insulating oxynitride, an insulating nitride oxide, an insulating metal oxide, an insulating metal oxynitride, an insulating metal nitride oxide, or the like can be used for the insulating layer. For example, a single layer or a stacked layer of an insulating material selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used as the insulating layer. Two or more selected from an oxide material, a nitride material, an oxynitride material, and a nitride oxide material may be used.

Note that in this specification and the like, a nitride oxide refers to a material that contains more nitrogen than oxygen. An oxynitride refers to a material that contains more oxygen than nitrogen. The content of each element can be measured by Rutherford backscattering spectrometry (RBS), for example.

As miniaturization and high integration of transistors progress, a problem such as leakage current may arise because of a thinner gate insulating layer. When a high-k material (a high dielectric constant material or a material with a high relative dielectric constant) is used for an insulating layer functioning as the gate insulating layer, a gate potential during operation of the transistor can be reduced while the physical thickness is maintained. A substance with a high dielectric constant, such as lead zirconate titanate (PZT), strontium titanate (SrTiO₃), or (Ba, Sr)TiO₃ (BST), can be used for the insulating layer in some cases. By contrast, when a material with a low relative dielectric constant is used for the insulating layer functioning as an interlayer film, parasitic capacitance generated between wirings can be reduced. Thus, a material is preferably selected depending on the function needed for the insulating layer.

Examples of materials with a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

In addition, examples of materials with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

There is no particular limitation on the formation method of the insulating material, and a variety of formation methods such as an evaporation method, an ALD method, a CVD method, a sputtering method, and a spin coating method can be employed.

For example, it is preferable that the insulating layer 154 and the insulating layer 167 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used. Examples of insulating materials through which impurities are less likely to pass, include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities do not easily pass is used for the insulating layer 154, impurity diffusion from under the insulating layer 154 can be inhibited, and the reliability of the transistor can be improved. That is, the reliability of a semiconductor device including the transistor can be improved. When the insulating material through which impurities are less likely to pass is used for the insulating layer 167, impurity diffusion from above the insulating layer 167 can be inhibited, and the reliability of the transistor can be improved. That is, the reliability of a semiconductor device including the transistor can be improved.

As the insulating layer, an insulating layer capable of functioning as a planarization layer may be used. Examples of materials capable of functioning as the planarization layer include an acrylic resin, polyimide, an epoxy resin, polyamide, polyimide amide, a siloxane resin, a benzocyclobutene resin, a phenol resin, and precursors of these resins. Besides the above organic materials, a low-k material (a low dielectric constant material or a material with a low relative dielectric constant), a siloxane resin, PSG (phosphosilicate glass), BPSG (borophosphosilicate glass), or the like can also be used. Note that a plurality of insulating layers formed of these materials may be stacked.

Note that the siloxane resin corresponds to a resin including a Si-O-Si bond formed using a siloxane-based material as a starting material. The siloxane resin may include an organic group (e.g., an alkyl group or an aryl group) or a fluoro group as a substituent. In addition, the organic group may include a fluoro group.

As the insulating layer 164 functioning as a dielectric of the capacitor Cs, a three-layer insulating layer (also referred to as “ZAZ”) including aluminum oxide sandwiched between two zirconium oxide layers may be used. ZAZ is a material with a high relative dielectric constant, and when ZAZ is used as a dielectric of the capacitor Cs, the area occupied by the capacitor Cs can be reduced.

### Conductive Layer

As a conductive material used for conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), ruthenium (Ru), and the like; an alloy containing the above metal element as a component; an alloy containing the above metal elements in combination; or the like can be used.

For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electrical conductivity, typified by polycrystalline silicon containing an impurity element such as phosphorus, or silicide such as nickel silicide may be used. There is no particular limitation on the formation method of the conductive material, and a variety of formation methods such as an evaporation method, an atomic layer deposition (ALD) method, a CVD method, a sputtering method, and a spin coating method can be employed.

A Cu-X alloy (X is Mn, Ni, Cr, Fe, Co, Mo, Ta, or Ti) may be used as the conductive material. A layer formed using a Cu-X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, can be used. A conductive material containing nitrogen, such as titanium nitride, tantalum nitride, or tungsten nitride, can also be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above conductive materials may be stacked and used. The conductive layer may have a stacked-layer structure in which a material containing the above-described metal element and a conductive material containing oxygen are combined, for example. Alternatively, a stacked-layer structure in which a material containing the above-described metal element and a conductive material containing nitrogen are combined may be used. Alternatively, a stacked-layer structure in which a material containing the above-described metal element, a conductive material containing oxygen, and a conductive material containing nitrogen are combined may be used.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

### Semiconductor Layer

For the semiconductor layer, a single crystal semiconductor, a polycrystalline semiconductor, a microcrystalline semiconductor, an amorphous semiconductor, or the like can be used alone or in combination. As a semiconductor material, a compound semiconductor (e.g., silicon germanium, silicon carbide, gallium arsenide, or a nitride semiconductor), as well as a single element semiconductor whose main component is a single element (e.g., silicon or germanium) may be used. As the compound semiconductor, an organic substance having semiconductor characteristics or a metal oxide having semiconductor characteristics (also referred to as an oxide semiconductor) can be used. These semiconductor materials may contain an impurity as a dopant.

For the semiconductor layer, single crystal silicon, polycrystalline silicon, microcrystalline silicon, and amorphous silicon may be used, for example. As the polycrystalline silicon, for example, low-temperature polysilicon (LTPS) may be used.

A transistor including amorphous silicon in its semiconductor layer can be formed over a large glass substrate, and can be manufactured at low cost. A transistor including polycrystalline silicon in its semiconductor layer has high field-effect mobility and enables high-speed operation. A transistor including microcrystalline silicon in its semiconductor layer has higher field-effect mobility and enables higher speed operation than the transistor including amorphous silicon.

The semiconductor layer may contain a layered material functioning as a semiconductor. The layered material generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typified by MoS₂), molybdenum selenide (typified by MoSe₂), molybdenum telluride (typified by MoTe₂), tungsten sulfide (typified by WS₂), tungsten selenide (typified by WSe₂), tungsten telluride (typified by WTe2), hafnium sulfide (typified by HfS₂), hafnium selenide (typified by HfSe₂), zirconium sulfide (typified by ZrS₂), and zirconium selenide (typified by ZrSe₂).

As described in the above embodiment, an oxide semiconductor has a band gap of 2 eV or more; thus, an OS transistor has an extremely low off-state current. The off-state current value per micrometer of channel width of an OS transistor at room temperature can be less than or equal to 1 aA (1×10⁻¹⁸ A), less than or equal to 1 zA (1×10⁻²¹ A), or less than or equal to 1 yA (1×10⁻²⁴ A). In addition, an OS transistor operates stably even in a high-temperature environment and has small change in characteristics. In an OS transistor, for example, the ratio between an on-state current and an off-state current is large even at an environmental temperature higher than or equal to 125° C. and lower than or equal to 150° C.; thus, an excellent switching operation can be performed. A soft error due to radiation such as cosmic rays is less likely to occur in a memory circuit or a memory element using an OS transistor, so that the memory circuit or the memory element can have increased reliability.

Thus, in this embodiment and the like, an OS transistor is preferably used as each of the transistor Tr21 to the transistor Tr25. Since an OS transistor has a high breakdown voltage between the source and the drain, the channel length can be shortened. The on-state current can be increased accordingly. The OS transistor is suitably used as a vertical-channel transistor.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element” and a “metal element” described in this specification and the like may refer to a metalloid element.

For example, as the metal oxide that can be used for the semiconductor layer of the OS transistor, it is possible to use indium oxide (In oxide), indium zinc oxide (In-Zn oxide), indium tin oxide (In-Sn oxide), indium titanium oxide (In-Ti oxide), indium gallium oxide (In-Ga oxide), indium gallium aluminum oxide (In-Ga-Al oxide), indium gallium tin oxide (In-Ga-Sn oxide), gallium zinc oxide (Ga-Zn oxide, also referred to as “GZO”), aluminum zinc oxide (Al-Zn oxide, also referred to as “AZO”), indium aluminum zinc oxide (In-Al-Zn oxide, also referred to as “IAZO”), indium tin zinc oxide (In-Sn-Zn oxide), indium titanium zinc oxide (In-Ti-Zn oxide), indium gallium zinc oxide (In-Ga-Zn oxide, also referred to as “IGZO”), indium gallium tin zinc oxide (In-Ga-Sn-Zn oxide, also referred to as “IGZTO”), or indium gallium aluminum zinc oxide (In-Ga-Al-Zn oxide, also referred to as “IGAZO” or “IAGZO”). Alternatively, an indium tin oxide containing silicon, a gallium tin oxide (a Ga-Sn oxide), an aluminum tin oxide (an Al-Sn oxide), or the like can be used.

By increasing the proportion of the number of indium atoms in the total number of atoms of all the metal elements contained in the metal oxide, the field-effect mobility of the transistor can be increased.

Note that the metal oxide may contain, instead of indium, one or more kinds of metal elements with large period numbers in the periodic table. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, when the transistor includes metal elements with larger period numbers, the field-effect mobility of the transistor can be increased in some cases. Examples of the metal elements with larger period numbers include metal elements that belong to Period 5 and metal elements that belong to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of metal elements in the main constituent elements contained in the metal oxide, the metal oxide has high crystallinity, so that diffusion of impurities in the metal oxide can be inhibited. Consequently, a change in electrical characteristics of the transistor is inhibited and the transistor can have high reliability.

By increasing the proportion of the number of atoms of the element M in the total number of atoms of metal elements in the main constituent elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is inhibited and the transistor can have high reliability.

Electrical characteristics and reliability of a transistor depend on the composition of the metal oxide used for the semiconductor layer. Thus, by changing the composition of the metal oxide in accordance with the electrical characteristics and reliability required for the transistor, the semiconductor device can have both excellent electrical characteristics and high reliability.

In the case where In—Zn oxide is used for the semiconductor layer of the OS transistor, a metal oxide in which the atomic proportion of indium is higher than or equal to the atomic proportion of zinc may be used. For example, a metal oxide in which the atomic ratio of metal elements is In:Zn=1:1, In:Zn=2:1, In:Zn=3:1, In:Zn=4:1, In:Zn=5:1, In:Zn=7:1, or In: Zn=10:1, or in the neighborhood thereof may be used.

In the case where In-Sn oxide is used for the semiconductor layer of the OS transistor, a metal oxide in which the atomic proportion of indium is higher than or equal to the atomic proportion of tin may be used. For example, a metal oxide in which the atomic ratio of metal elements is In:Sn=1:1, In:Sn=2:1, In:Sn=3:1, In:Sn=4:1, In:Sn=5:1, In:Sn=7:1, or In: Sn=10:1, or in the neighborhood thereof may be used.

In the case where In—Sn—Zn oxide is used for the semiconductor layer of the OS transistor, a metal oxide in which the atomic proportion of indium is higher than the atomic proportion of tin may be used. It is further preferable to use a metal oxide in which the atomic proportion of zinc is higher than the atomic proportion of tin. For example, a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof may be used.

In the case where In-Al-Zn oxide is used for the semiconductor layer of the OS transistor, a metal oxide in which the atomic proportion of indium is higher than the atomic proportion of aluminum may be used. It is further preferable to use a metal oxide in which the atomic proportion of zinc is higher than the atomic proportion of aluminum. For example, a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof may be used.

In the case of using In-Ga-Zn oxide for the semiconductor layer of the OS transistor, a metal oxide in which the proportion of the number of indium atoms in the number of atoms of the metal elements is higher than the proportion of the number of gallium atoms may be used. It is further preferable to use a metal oxide in which the atomic proportion of zinc is higher than the atomic proportion of gallium. For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used in the semiconductor layer.

In the case where In—M—Zn oxide is used for the semiconductor layer of the OS transistor, a metal oxide in which the proportion of the number of indium atoms in the number of atoms of the metal elements is higher than the proportion of the number of element M atoms may be used. It is further preferable to use a metal oxide in which the atomic proportion of zinc is higher than the atomic proportion of the element M. For example, a metal oxide in which the atomic ratio of metal elements is In:M:Zn=2:1:3, In:M:Zn=3:1:2, In:M:Zn=4:2:3, In:M:Zn=4:2:4.1, In:M:Zn =5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or in the neighborhood thereof may be used in the semiconductor layer.

In the case where In—M—Zn oxide is used for the semiconductor layer, a metal oxide in which the atomic ratio of metal elements is In:M:Zn=1:3:2 [atomic ratio] or in the neighborhood thereof, In:M:Zn=1:3:4 [atomic ratio] or in the neighborhood thereof, In:M:Zn=1:1:0.5 [atomic ratio] or in the neighborhood thereof, In:M:Zn=1:1:1 [atomic ratio] or in the neighborhood thereof, In:M:Zn=1:1:1.2 [atomic ratio] or in the neighborhood thereof, In:M:Zn=1:1:2 [atomic ratio] or in the neighborhood thereof, or In:M:Zn=4:2:3 [atomic ratio] or in the neighborhood thereof may be used. Note that a composition in the neighborhood of an atomic ratio includes ±30 % of an intended atomic ratio. It is preferable to use gallium as the element M.

In the case where a plurality of metal elements are contained as the element M, the sum of the atomic ratios of the metal elements can be the atomic ratio of the element M. In the case of In—Ga—Al—Zn oxide in which gallium and aluminum are contained as the element M, for example, the sum of the atomic ratio of gallium and the atomic ratio of aluminum can be the atomic ratio of the element M. The atomic ratio of indium to the element M to zinc is preferably within the ranges given above.

It is preferable to use a metal oxide in which the proportion of the number of indium atoms in the total number of atoms of metal elements in the main constituent elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case where In—M—Zn oxide is used for the semiconductor layer, the proportion of the number of indium atoms in the total number of atoms of indium, the element M, and zinc is preferably within the ranges given above.

As described above, by increasing the proportion of the number of indium atoms in the total number of atoms of metal elements in the main constituent elements contained in the metal oxide, the field-effect mobility of the transistor can be increased. With the use of such a transistor, a circuit capable of high-speed operation can be formed. Furthermore, the area occupied by the circuit can be reduced.

For analysis of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used for forming the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion ratio of zinc in the target in some cases. Specifically, the atomic proportion of zinc contained in the metal oxide may be approximately higher than or equal to 40% and lower than or equal to 90% of the atomic proportion of zinc contained in the target.

When the metal oxide is deposited by a sputtering method, the above atomic ratio is not limited to the atomic ratio of the metal oxide deposited and may be the atomic ratio of a sputtering target used for depositing the metal oxide.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where light irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state; thus, the amount of change in threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. That is, the amount of change in the threshold voltage of the transistor in the PBTS test can be small. Meanwhile, with use of a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, at the interface between a metal oxide containing a large amount of gallium and the gate insulating layer, gallium is bonded to excess oxygen in the gate insulating layer, which probably generates trap sites of carriers (here, electrons) easily. This might cause the change in the threshold voltage when a positive potential is supplied to a gate and carriers are trapped at the interface between the semiconductor layer and the gate insulating layer.

More specifically, in the case where In-Ga-Zn oxide is used for the semiconductor layer, a metal oxide in which the atomic proportion of indium is higher than the atomic proportion of gallium can be used for the semiconductor layer. It is further preferable to use a metal oxide in which the atomic proportion of zinc is higher than the atomic proportion of gallium. In other words, a metal oxide in which the atomic proportions of metal elements satisfies In>Ga and Zn >Ga is preferably used for the semiconductor layer.

For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used for the semiconductor layer of the OS transistor.

The semiconductor layer of the OS transistor is preferably formed using a metal oxide having the following compositions: the proportion of the number of gallium atoms in the number of atoms of the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that an oxygen vacancy (Vo) is less likely to be generated in the metal oxide when the metal oxide contains gallium.

A metal oxide not containing gallium may be used for the semiconductor layer of the OS transistor. For example, In—Zn oxide can be used for the semiconductor layer. In this case, when the proportion of the number of indium atoms in the number of atoms of the metal elements contained in the metal oxide is increased, the field-effect mobility of the transistor can be increased. By contrast, when the proportion of the number of zinc atoms in the number of atoms of the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide in which the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer. Furthermore, a metal oxide in which the atomic proportion of zinc is higher than the atomic proportion of the element M is preferably used.

The use of a metal oxide having a low content percentage of the element M for the semiconductor layer achieves the transistor that is highly reliable against positive bias application. With use of the transistor as a transistor that is required to have high reliability against positive bias application, a highly reliable semiconductor device can be achieved.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or in the neighborhood thereof and a second metal oxide layer having a composition of In:Zn=4:1 [atomic ratio] or in the neighborhood thereof and being provided over the first metal oxide layer may be used.

It is preferable to use a metal oxide layer having crystallinity as the semiconductor layer. For example, a metal oxide layer having a CAAC (c-axis aligned crystal) structure, a polycrystalline structure, a microcrystalline (nc: nano-crystal) structure, or the like can be used. With use of a metal oxide layer having crystallinity as the semiconductor layer, the density of defect states in the semiconductor layer can be reduced, which achieves a highly reliable display device.

The higher the crystallinity of the metal oxide layer used as the semiconductor layer is, the lower the density of defect states in the semiconductor layer can be. By contrast, the use of a metal oxide layer having low crystallinity achieves a transistor through which a large amount of current can flow.

In the case where the metal oxide layer is formed by a sputtering method, the higher the substrate temperature (the stage temperature) in the formation is, the higher the crystallinity of the metal oxide layer can be. The metal oxide layer with higher crystallinity can be formed as the proportion of a flow rate of an oxygen gas to the whole deposition gas (also referred to as oxygen flow rate ratio) used in formation is increased.

The semiconductor layer of the OS transistor may have a stacked-layer structure of two or more metal oxide layers having different crystallinities. For example, a stacked-layer structure of a first metal oxide layer and a second metal oxide layer provided over the first metal oxide layer may be employed; the second metal oxide layer may include a region having higher crystallinity than the first metal oxide layer. Alternatively, the second metal oxide layer may include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities may be formed. The two or more metal oxide layers included in the semiconductor layer may have different compositions.

In the case where an oxide semiconductor is used for the semiconductor layer 163, a material containing hydrogen is preferably used for the insulating layer 157 and the insulating layer 159. When the insulating layer containing hydrogen is in contact with the oxide semiconductor, the oxide semiconductor in a region in contact with the insulating layer becomes an n-type semiconductor and can function as a source region or a drain region. For example, a material containing silicon, nitrogen, and hydrogen is used for the insulating layer. Specifically, silicon nitride containing hydrogen or silicon nitride oxide containing hydrogen is used.

The thickness of each of the insulating layer 157 and the insulating layer 159 is preferably larger than or equal to 1 nm and smaller than or equal to 15 nm, further preferably larger than or equal to 2 nm and smaller than or equal to 10 nm, still further preferably larger than or equal to 3 nm and smaller than or equal to 7 nm, and yet still further preferably larger than or equal to 3 nm and smaller than or equal to 5 nm. In the case where an oxide semiconductor is used for the semiconductor layer 163, the region of the semiconductor layer 163 that is in contact with the insulating layer 157 containing hydrogen and the region of the semiconductor layer 163 that is in contact with the insulating layer 159 containing hydrogen function as a source region and a drain region. The sizes of the source region and the drain region formed in the semiconductor layer 163 can be controlled by adjusting the thicknesses of the insulating layer 157 and the insulating layer 159.

The thickness of the insulating layer 158 is preferably larger than or equal to 1 nm and smaller than or equal to 50 nm, further preferably larger than or equal to 2 nm and smaller than or equal to 30 nm, still further preferably larger than or equal to 3 nm and smaller than or equal to 20 nm. The size of the channel formation region of the semiconductor layer 163 can be controlled by adjusting the thickness of the insulating layer 158.

The thicknesses of the insulating layer 157, the insulating layer 158, and the insulating layer 159 are set as appropriate in accordance with the characteristics required for the transistor.

The insulating layer 157, the insulating layer 158, and the insulating layer 159 are preferably formed successively without exposure to the atmospheric environment. When the insulating layer 157, the insulating layer 158, and the insulating layer 159 are successively formed without exposure to the atmospheric environment, impurities or moisture in the atmospheric environment can be prevented from being attached to the interface between the insulating layer 157 and the insulating layer 158 and the vicinity thereof and the interface between the insulating layer 158 and the insulating layer 159 and the vicinity thereof.

In the case where an oxide semiconductor is used for the semiconductor layer 163, a conductive material that makes the oxide semiconductor an n-type semiconductor is preferably used for the conductive layer 155 in contact with the semiconductor layer 163 and the conductive layer 161 in contact with the semiconductor layer 163. For example, a conductive material containing nitrogen is used. For example, a conductive material containing nitrogen and titanium or tantalum is used. Another conductive material may be provided so as to overlap with the conductive material containing nitrogen.

Meanwhile, for the insulating layer 158, a material which contains oxygen and a reduced amount of hydrogen is preferably used. For example, a material containing silicon and oxygen is used. Specifically, silicon oxide, silicon oxynitride, or the like is used. Since hydrogen is an impurity element in an oxide semiconductor, when the semiconductor layer 163, which is an oxide semiconductor, and the insulating layer 158, which includes a reduced amount of hydrogen, are in contact with each other, the semiconductor layer 163 is less likely to become an n-type layer. Furthermore, when the semiconductor layer 163, which is an oxide semiconductor, and the insulating layer 158 containing oxygen are in contact with each other, oxygen vacancies in the semiconductor layer 163 are reduced and the transistor has stable characteristics and improved reliability.

When an oxide semiconductor is used for the semiconductor layer 163, the insulating layer 158 preferably includes excess oxygen. In this specification and the like, excess oxygen refers to oxygen that is released by heating. In the case where a material containing excess oxygen is used for the insulating layer 158, a material through which oxygen is less likely to pass is preferably used for the insulating layer 157 and the insulating layer 159. Examples of the material through which oxygen is less likely to pass include a nitride of silicon and an oxide containing one or both of aluminum and hafnium. When the material through which oxygen is less likely to pass is used for the insulating layer 157 and the insulating layer 159, excess oxygen contained in the insulating layer 158 is less likely to be released to a lower layer or an upper layer. Thus, a sufficient amount of oxygen can be supplied to the oxide semiconductor. For example, it is possible to use a structure in which an insulating layer containing silicon and oxygen (the insulating layer 158) is provided between two insulating layers containing silicon and nitrogen (the insulating layer 157 and the insulating layer 159).

When an oxide semiconductor is used for the semiconductor layer 163 and a material containing hydrogen is used for the insulating layer 157 and the insulating layer 159, the region of the semiconductor layer 163 that is in contact with the insulating layer 157 and the region of the semiconductor layer 163 that is in contact with the insulating layer 159 are supplied with hydrogen and become n-type regions. Thus, the region of the semiconductor layer 163 that is in contact with the conductive layer 161 and the region of the semiconductor layer 163 that is in contact with the insulating layer 159 function as one of a source (a source region) and a drain (a drain region). The region of the semiconductor layer 163 that is in contact with the conductive layer 155 and the region of the semiconductor layer 163 that is in contact with the insulating layer 157 function as the other of the source (the source region) and the drain (the drain region).

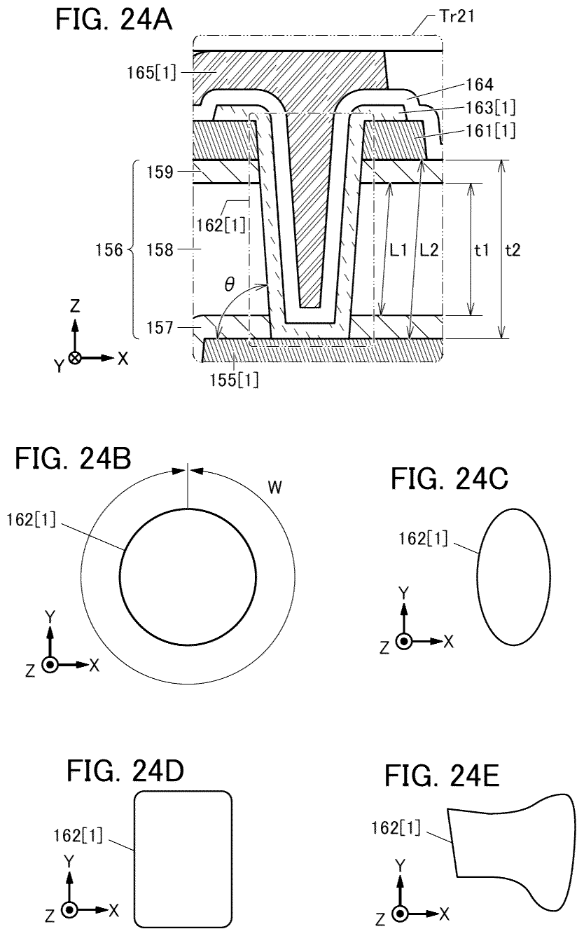

FIG. 24A is an enlarged view of a cross section of the transistor Tr21 illustrated in FIG. 23A. In the transistor Tr21, which is a VFET having the above structure, the length of the side surface of the insulating layer 158 seen from the X direction or the Y direction corresponds to a channel length L (a channel length L1) (see FIG. 24A). Hence, the channel length L of the transistor Tr21 is determined in accordance with a thickness t1 of the insulating layer 158.

A material that contains no hydrogen or an extremely small amount of hydrogen may be used for the insulating layer 157 and the insulating layer 159. For example, silicon nitride that contains an extremely small amount of hydrogen or silicon nitride oxide that contains an extremely small amount of hydrogen may be used. In that case, the region of the semiconductor layer 163[1] that is in contact with the insulating layer 157 and the region of the semiconductor layer 163[1] that is in contact with the insulating layer 159 do not become n-type regions. Thus, the region of the semiconductor layer 163[1] that is in contact with the conductive layer 161[1] functions as one of the source (the source region) and the drain (the drain region). The region of the semiconductor layer 163[1] that is in contact with the conductive layer 155[1] functions as the other of the source (the source region) and the drain (the drain region). The region of the semiconductor layer 163[1] that is in contact with the insulating layer 158 functions as the channel formation region.

In that case, the channel length L (a channel length L2) is the sum of the lengths of side surfaces of the insulating layer 157, the insulating layer 158, and the insulating layer 159 seen from the X direction or the Y direction. Hence, the channel length L of the transistor Tr21 is determined in accordance with a thickness t2, which is the sum of the thicknesses of the insulating layer 157, the insulating layer 158, and the insulating layer 159.

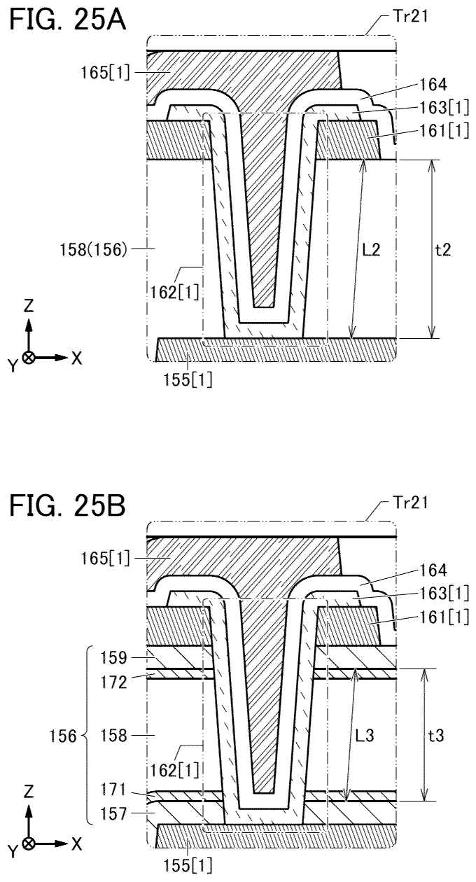

FIG. 25A and FIG. 25B illustrate variation examples of FIG. 24A. For example, a structure in which the insulating layer 157 and the insulating layer 159 are not provided and only the insulating layer 158 is provided to be in contact with the conductive layer 155[1] and the conductive layer 161[1] may be employed (see FIG. 25A). In that case, the length of the side surface of the insulating layer 158 seen from the X direction or the Y direction is the channel length L (the channel length L2). Thus, the channel length L of the transistor Tr21 is determined in accordance with the thickness t2 of the insulating layer 158. In the case of the structure illustrated in FIG. 25A, the insulating layer 158 is referred to as the insulating layer 156 in some cases. Note that the channel length L illustrated in FIG. 25A can be rephrased as the channel length L2 illustrated in FIG. 24A, and the thickness t2 illustrated in FIG. 25A can be rephrased as the thickness t2 illustrated in FIG. 24A.

When an oxide semiconductor is used for the semiconductor layer 163[1], a material containing hydrogen is used for the insulating layer 157 and the insulating layer 159, and a material containing excess oxygen is used for the insulating layer 158, hydrogen contained in the insulating layer 157 and the insulating layer 159 is bonded to excess oxygen contained in the insulating layer 158, whereby the region of the semiconductor layer 163[1] that is in contact with the insulating layer 157 and the region of the semiconductor layer 163[1] that is in contact with the insulating layer 159 are not supplied with a sufficient amount of hydrogen and are less likely to become n-type regions. Likewise, the region of the semiconductor layer 163[1] that is in contact with the insulating layer 158 is not supplied with a sufficient amount of oxygen.

In order solve such a problem, an insulating layer 171 through which oxygen and nitrogen are less likely to pass may be provided between the insulating layer 157 and the insulating layer 158, and an insulating layer 172 through which oxygen and nitrogen are less likely to pass may be provided between the insulating layer 159 and the insulating layer 158 (see FIG. 25B). A material through which oxygen and nitrogen are less likely to pass can be achieved by using, for example, a nitride of silicon. Note that in the case of the structure illustrated in FIG. 25B, the insulating layer 157, the insulating layer 171, the insulating layer 158, the insulating layer 172, and the insulating layer 159 are collectively referred to as the insulating layer 156 in some cases. When the material through which oxygen is less likely to pass is used for the insulating layer 171 and the insulating layer 172, bonding of hydrogen contained in the insulating layer 157 and the insulating layer 159 to excess oxygen contained in the insulating layer 158 is hindered. Accordingly, a sufficient amount of hydrogen is supplied to the region of the semiconductor layer 163[1] that is in contact with the insulating layer 157 and the region of the semiconductor layer 163[1] that is in contact with the insulating layer 159. Likewise, a sufficient amount of oxygen is supplied to the region of the semiconductor layer 163[1] that is in contact with the insulating layer 158.

In that case, a channel length L3 is the sum of the lengths of side surfaces of the insulating layer 171, the insulating layer 158, and the insulating layer 172 seen from the X direction or the Y direction. Thus, the channel length L of the transistor Tr21 is determined in accordance with a thickness t3, which is the sum of the thicknesses of the insulating layer 171, the insulating layer 158, and the insulating layer 172.

The channel length L of the transistor Tr21 of one embodiment of the present invention is determined in accordance with the thickness of the insulating layer provided between the conductive layer 161[1] and the conductive layer 155[1]. As a result, the transistor with a short channel length L can be formed with high accuracy. In addition, variations in characteristics among a plurality of transistors Tr21 are also reduced. Thus, the semiconductor device including the transistors Tr21 can operate stably and have high reliability. When the variations in characteristics are reduced, the circuit design flexibility of the semiconductor device is increased and the operation voltage can be reduced. Thus, the power consumption of the semiconductor device can be reduced.

Although this embodiment illustrates the structure including three insulating layers (the insulating layer 157, the insulating layer 158, and the insulating layer 159) or five insulating layers (the insulating layer 157, the insulating layer 158, the insulating layer 159, the insulating layer 171, and the insulating layer 172) between the conductive layer 155[1] and the conductive layer 161[1], the number of insulating layers between the conductive layer 155[1] and the conductive layer 161[1] is not limited thereto. The number of insulating layers between the conductive layer 155[1] and the conductive layer 161[1] may be one, two, four, six, or more.

In order to improve the coverage with the semiconductor layer 163[1], the insulating layer 164, and the conductive layer 165[1] formed in the opening 162[1], a taper angle 0 of the side surface of the opening 162[1], i.e., the taper angle 0 of the side surface of each of the insulating layer 157, the insulating layer 158, and the insulating layer 159 is greater than or equal to 45° and less than or equal to 90°, preferably greater than or equal to 50° and less than or equal to 75°. Note that the taper angle 0 of the side surface of the layer (the insulating layer, the conductive layer, or the semiconductor layer) refers to the angle formed between the bottom surface and the side surface of the layer (see FIG. 24A).

Since the semiconductor layer 163[1] is provided in the opening 162[1], the length of the circumference of the opening 162[1] seen from the Z direction is a channel width W of the transistor Tr21 (see FIG. 24B). The circumference is determined, for example, at the position of half of the thickness t1 of the insulating layer 158 or at the position of half of the thickness t2 of the insulating layer 158. Note that the length of the circumference of the opening 162[1] at an arbitrary position may be regarded as the channel width W as necessary. For example, the length of the circumference at the lowest portion of the opening 162[1] may be regarded as the channel width W, or the length of the circumference at the uppermost portion of the opening 162[1] may be regarded as the channel width W.

In the memory device of one embodiment of the present invention, the channel length L is preferably shorter than at least the channel width W. In one embodiment of the present invention, the channel length L is greater than or equal to 0.1 times and less than or equal to 0.99 times, preferably greater than or equal to 0.5 times and less than or equal to 0.8 times the channel width W.

Although the outline (the planar shape) of the opening 162[1] seen from the Z direction is circular in FIG. 24B, the outline is not limited to this. For example, the outline of the opening 162[1] seen from the Z direction may be elliptical (see FIG. 24C) or rectangular (see FIG. 24D). Note that FIG. 24D illustrates a rectangular shape having rounded corner portions. For another example, the outline of the opening 162[1] seen from the Z direction may have a shape including one or both of a straight portion and a curved portion (see FIG. 24E).

Note that the opening 162[1] preferably has a minute size. For example, the maximum width of the opening 162[1] (the maximum diameter in the case where the opening 162[1] is circular) seen from the Z direction is preferably less than or equal to 60 nm, further preferably less than or equal to 50 nm, still further preferably less than or equal to 40 nm, and yet still further preferably less than or equal to 30 nm. The maximum width of the opening 162[1] seen from the Z direction may be less than or equal to 20 nm. Note that the minimum width of the opening 162[1] (the minimum diameter in the case where the opening 162[1] is circular) seen from the Z direction is preferably greater than or equal to 1 nm, further preferably greater than or equal to 5 nm. Such a minute opening 162[1] is preferably formed by a lithography method using an electron beam or short-wavelength light such as EUV light.

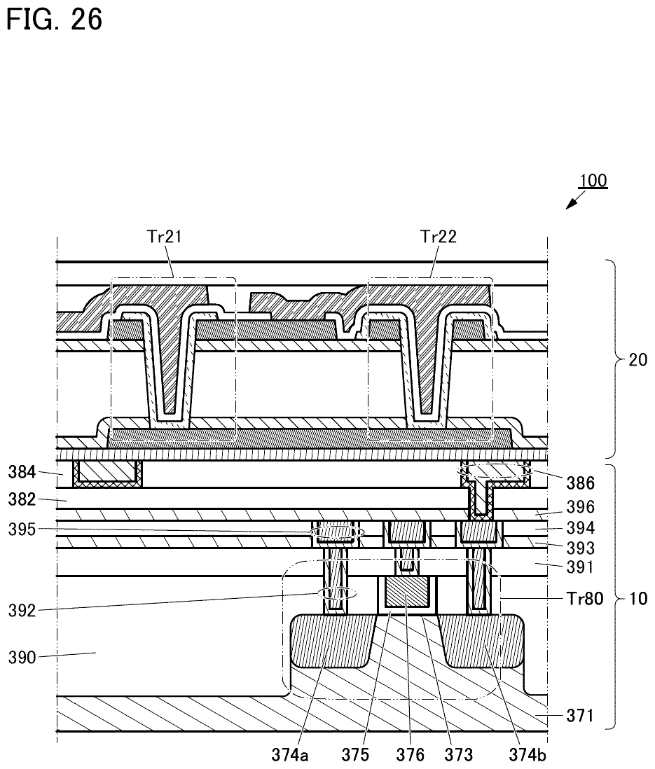

FIG. 26 illustrates a stacked-layer structure example of the memory cell 100 that is a kind of a semiconductor device. The memory cell 100 illustrated in FIG. 26 includes the layer 20 including the second memory circuit 120 above the layer 10 including the first memory circuit 110. FIG. 26 illustrates the structure illustrated in FIG. 23A as an example of that of the second memory circuit 120 included in the layer 20. In order to reduce repeated description, the description of the second memory circuit 120 is omitted here.

In FIG. 26, a transistor Tr80 is illustrated as an example of a transistor included in the first memory circuit 110. The transistor Tr80 is provided on a substrate 371 and includes a conductive layer 376 functioning as a gate, an insulating layer 375 functioning as a gate insulating layer, a semiconductor region 373 formed of part of the substrate 371, and a low-resistance region 374a and a low-resistance region 374b functioning as a source region and a drain region. The transistor Tr80 can be a p-channel transistor or an n-channel transistor. As the substrate 371, a single crystal silicon substrate can be used, for example.

Here, in the transistor Tr80 illustrated in FIG. 26, the semiconductor region 373 (part of the substrate 371) in which a channel is formed has a protruding shape. In addition, the conductive layer 376 is provided to cover the side surface and the top surface of the semiconductor region 373 with the insulating layer 375 therebetween. Note that a material adjusting the work function may be used for the conductive layer 376. Such a transistor Tr80 is also referred to as a FIN-type transistor because it utilizes a protruding portion of the semiconductor substrate. Note that an insulating layer functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor Tr80 illustrated in FIG. 26 is an example and the structure is not limited thereto; an appropriate transistor is used in accordance with a circuit structure or a driving method.

Wiring layers each provided with an interlayer film, a wiring, a plug, and the like may be provided in the layer 10 and the layer 20. A plurality of wiring layers can be provided in accordance with the design. Furthermore, in this specification and the like, a wiring and a plug electrically connected to the wiring may be a single component. That is, there are cases where part of a conductive layer functions as a wiring and another part of the conductive layer functions as a plug.

For example, an insulating layer 390, an insulating layer 391, an insulating layer 393, and an insulating layer 394 are stacked in this order over the transistor Tr80 as interlayer films. A conductive layer 395 or the like are embedded in the insulating layer 390, the insulating layer 391, the insulating layer 393, and the insulating layer 394. The conductive layer 395 is connected to the second memory circuit 120 provided in the layer 20. Note that a conductive layer 392 and the conductive layer 395 function as a contact plug or a wiring.

The insulating layers functioning as interlayer films may also function as planarization films that cover uneven shapes therebelow. For example, the top surface of the insulating layer 391 may be subjected to CMP treatment or the like to have improved planarity.

A wiring layer may be provided over the insulating layer 394 and the conductive layer 395. For example, in FIG. 26, an insulating layer 396, an insulating layer 382, and an insulating layer 384 are provided to be stacked sequentially over the insulating layer 394 and the conductive layer 395. A conductive layer 386 is formed in the insulating layer 396, the insulating layer 382, and the insulating layer 384. The conductive layer 386 functions as a contact plug or a wiring.

The structure described in this embodiment can be used in an appropriate combination with the structures described in the other embodiments.

### Embodiment 5

In this embodiment, application examples of the memory cell 100, the memory device 300, and the memory system 400, which are semiconductor devices of one embodiment of the present invention, are described.

When the semiconductor device of one embodiment of the present invention is employed for an electronic device, the influence of a soft error on the electronic device can be reduced and the reliability of the electronic device can be increased. With the use of the semiconductor device of one embodiment of the present invention, a reduction in power consumption of the electronic device can be achieved. Heat generation from a circuit can be reduced owing to low power consumption; thus, the adverse influence on the circuit itself, a peripheral circuit, and a module can be reduced. Furthermore, the use of the semiconductor device of one embodiment of the present invention can achieve an electronic device that operates stably even in a high temperature environment. Thus, the reliability of the electronic device can be increased.

The semiconductor device according to one embodiment of the present invention can be used for a variety of electronic components. For example, the semiconductor device can be applied to a cache and a register of a microprocessor such as a CPU, a DSP (Digital Signal Processor), or a GPU (Graphics Processing Unit). The microprocessor may be constructed with a PLD (Programmable Logic Device) such as an FPGA (Field Programmable Gate Array) or an FPAA (Field Programmable Analog Array).

Thus, the semiconductor device of one embodiment of the present invention can be applied to, for example, a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

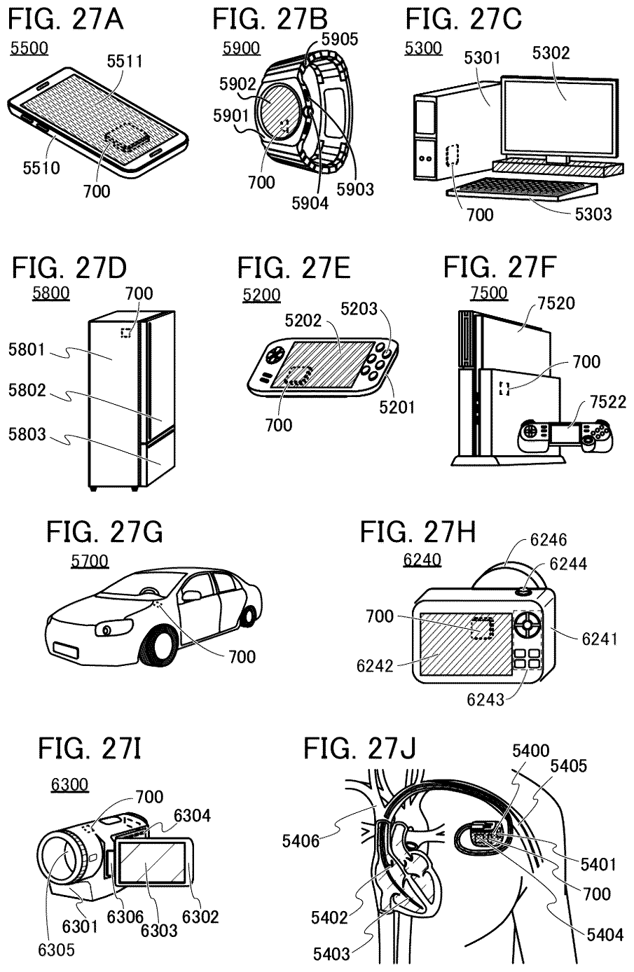

An example of an electronic device including the semiconductor device of one embodiment of the present invention is described. FIG. 27A to FIG. 27J illustrate electronic devices each including an electronic component 700 that includes the semiconductor device of one embodiment of the present invention.

cellular Phone

An information terminal 5500 illustrated in FIG. 27A is a cellular phone (a smartphone), which is a kind of information terminal. The information terminal 5500 includes a housing 5510 and a display portion 5511, and as input interfaces, a touch panel is provided in the display portion 5511 and a button is provided in the housing 5510.

wearable Terminal
FIG. 27B illustrates an information terminal 5900 that is an example of a wearable terminal. The information terminal 5900 includes a housing 5901, a display portion 5902, an operation switch 5903, an operation switch 5904, a band 5905, and the like.

### Information Terminal

FIG. 27C illustrates a desktop information terminal 5300. The desktop information terminal 5300 includes a main body 5301 of the information terminal, a display portion 5302, and a keyboard 5303.

Although the smartphone, the wearable terminal, and the desktop information terminal are respectively illustrated in FIG. 27A to FIG. 27C as examples of the electronic device, the semiconductor device of one embodiment of the present invention can be applied to information terminals other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### Household Appliance

FIG. 27D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal or the like via the Internet or the like.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### Game Machines

FIG. 27E illustrates a portable game machine 5200 as an example of a game machine. The portable game machine 5200 includes a housing 5201, a display portion 5202, a button 5203, and the like.

In addition, FIG. 27F illustrates a stationary game machine 7500 as another example of a game machine. The stationary game machine 7500 includes a main body 7520 and a controller 7522. Note that the controller 7522 can be connected to the main body 7520 with or without a wire. Although not illustrated in FIG. 27F, the controller 7522 can include a display portion that displays a game image, and an input interface besides a button, such as a touch panel, a stick, a rotating knob, or a sliding knob, for example. Moreover, the shape of the controller 7522 is not limited to that illustrated in FIG. 27F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display device such as a television device, a personal computer display, a game display, or a head-mounted display.

As an example of a game machine, FIG. 27E illustrates a portable game machine. In addition, FIG. 27F illustrates a home-use stationary game machine. Note that the game machine of one embodiment of the present invention is not limited to a portable game machine and a home-use stationary game machine. Examples of game machines of one embodiment of the present invention include an arcade game machine installed in entertainment facilities (e.g., a game center and an amusement park), a throwing machine for batting practice installed in sports facilities, and the like.

Moving vehicle

The semiconductor device described in the above embodiment can be used for a motor vehicle, which is a moving vehicle, and around the driver's seat in a motor vehicle.

FIG. 27G illustrates a motor vehicle 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the motor vehicle 5700. In addition, a display device showing the above information may be provided around the driver's seat.

In particular, the display device can compensate for the view obstructed by a pillar or the like, blind areas for the driver's seat, and the like by displaying a video from an imaging device (not illustrated) provided for the motor vehicle 5700, which can increase safety. That is, display of an image from an imaging device provided on the outside of the motor vehicle 5700 can fill in blind areas and increase safety.

Note that although the motor vehicle is described above as an example of a moving vehicle, the moving vehicle is not limited to the motor vehicle. Examples of moving vehicles include a train, a monorail train, a ship, and a flying object (a helicopter, an unmanned aircraft (a drone), an airplane, and a rocket).

### Camera

The semiconductor device described in the above embodiment can be employed for a camera.

FIG. 27H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that, here, although the digital camera 6240 is configured such that the lens 6246 is detachable from the housing 6241 for replacement, the lens 6246 may be integrated with the housing 6241. In addition, the digital camera 6240 may be configured to be additionally equipped with a stroboscope, a viewfinder, or the like.

Video Camera The semiconductor device described in the above embodiment can be employed for a video camera.

FIG. 27I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Video on the display portion 6303 may be switched in accordance with the angle at the joint 6306 between the first housing 6301 and the second housing 6302.

### ICD

The semiconductor device described in the above embodiment can be employed for an implantable cardioverter-defibrillator (ICD).

FIG. 27J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 has a function of a pacemaker and paces the heart when the heart rate is out of a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for sensing the heart rate. In addition, in the ICD main unit 5400, data on the heart rate obtained by the sensor or the like, the number of times the treatment with pacing is performed, and the time taken for the treatment, for example, can be stored in the electronic component 700.

In addition, the antenna 5404 can receive electric power, and the battery 5401 is charged with the electric power. Furthermore, when the ICD main unit 5400 includes a plurality of batteries, safety can be increased. Specifically, even when some of the batteries in the ICD main unit 5400 run out, the other batteries can function; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

The semiconductor device described in the above embodiment is employed for the ICD main unit 5400, whereby the ICD main unit 5400 can have low power consumption. Furthermore, the size and weight of a storage battery can be reduced owing to low power consumption. Moreover, heat generation of the ICD main unit 5400 can be reduced owing to low power consumption; thus, a load on the human body can be reduced.

### Computer

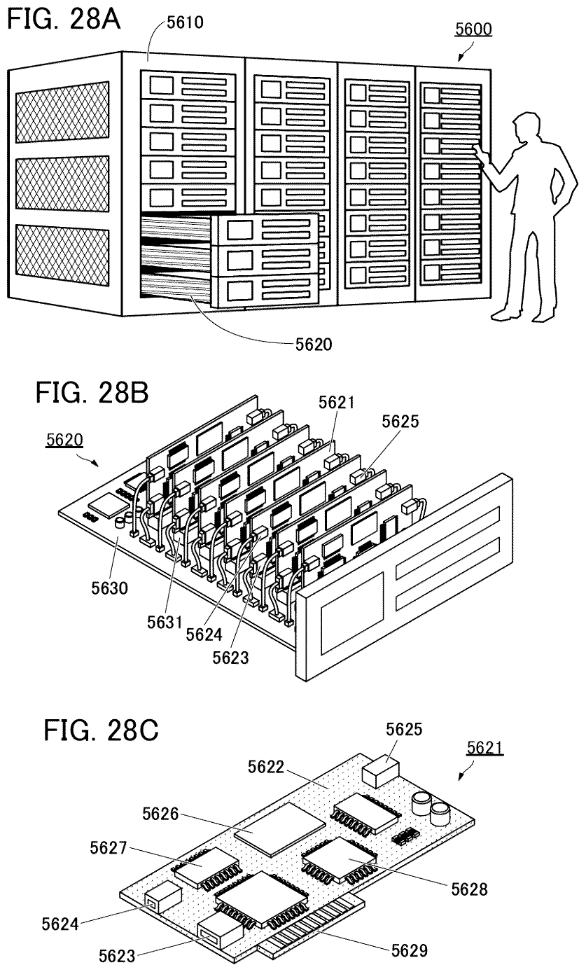

A computer 5600 illustrated in FIG. 28A is an example of a large computer (a supercomputer) mainly used for scientific computation. In scientific computation, an enormous amount of arithmetic operation needs to be processed at high speed; hence, power consumption is high and chips generate a large amount of heat. For example, a data center including a plurality of super computers uses an enormous amount of digital data. Specifically, the amount of digital data in the world is estimated to exceed 1024 (yotta) byte or 1030 (quetta) byte.

When the semiconductor device of one embodiment of the present invention is employed for the computer 5600, the influence of a soft error on the computer 5600 can be reduced and the reliability of the computer 5600 can be increased. In addition, when the semiconductor device of one embodiment of the present invention is employed for the computer 5600, a supercomputer with low power consumption can be achieved. Moreover, heat generation from a circuit can be reduced owing to low power consumption; thus, the influence of heat generation on the circuit itself, a peripheral circuit, and a module can be reduced. When the semiconductor device of one embodiment of the present invention is employed, a supercomputer with low power consumption can be achieved. Thus, the amount of digital data in the world is expected to be reduced, leading to a great contribution to global warming countermeasures.

In the computer 5600, a plurality of rack mount computers 5620 are stored in a rack 5610. The computer 5620 can have a structure in a perspective view illustrated in FIG. 28B, for example. In FIG. 28B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 28C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 28C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 700 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device.

The computer 5600 can also function as a parallel computer. When the computer 5600 is used as a parallel computer, large-scale computation necessary for artificial intelligence learning and inference can be performed, for example.

The structure described in this embodiment can be used in an appropriate combination with the structures described in the other embodiments.

### Embodiment 6

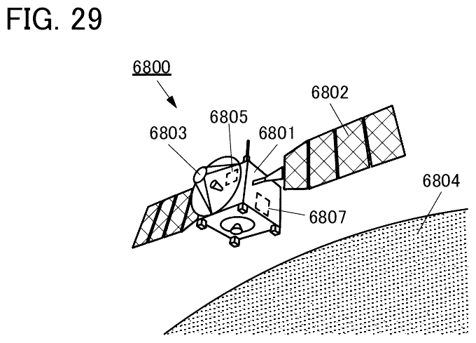

The semiconductor device of one embodiment of the present invention includes an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space. In this embodiment, a specific example of the case where the semiconductor device of one embodiment of the present invention is used in space equipment will be described with reference to FIG. 29.

FIG. 29 illustrates an artificial satellite 6800 as an example of space equipment. The artificial satellite 6800 includes a body 6801, solar panels 6802, an antenna 6803, a secondary battery 6805, and a control device 6807. In FIG. 29, a planet 6804 in outer space is illustrated as an example. Note that outer space refers to, for example, space at an altitude greater than or equal to 100 km, and outer space in this specification may also include thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 may be provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that the semiconductor device that is one embodiment of the present invention and includes an OS transistor is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, the present invention is not limited thereto. The semiconductor device of one embodiment of the present invention can be suitably used for space equipment such as a spacecraft, a space capsule, or a space probe, for example.

The structure described in this embodiment can be used in an appropriate combination with the structures described in the other embodiments.

### REFERENCE NUMERALS

100: memory cell, 101: wiring, 102: wiring, 103: wiring, 104: wiring, 105: wiring, 106: wiring, 107: wiring, 110: first memory circuit, 120: second memory circuit, 200: memory cell array, 300: memory device

1. A semiconductor device comprising:
a first memory circuit and a second memory circuit,
wherein the semiconductor device: is configured to compare a logic value of first data retained in the first memory circuit with a logic value of second data retained in the second memory circuit,
wherein the semiconductor device is configured to output first signal corresponding to a comparison result,
wherein the first memory circuit comprises a transistor comprising silicon in a channel formation region, and
wherein the second memory circuit comprises a transistor comprising an oxide semiconductor in a channel formation region.

2. The semiconductor device according to claim 1, wherein the semiconductor device is configured to output a potential as the first signal when the logic value of the first data and the logic value of the second data are different from each other.

3. The semiconductor device according to claim 1, further comprising:
a region where the first memory circuit and the second memory circuit overlap with each other.

4. A semiconductor device comprising:
a first memory circuit and a second memory circuit,
wherein the first memory circuit comprises a first inverter circuit, a second inverter circuit, a first transistor, and a second transistor,
wherein an output of the first inverter circuit is electrically connected to an input of the second inverter circuit,
wherein an output of the second inverter circuit is electrically connected to an input of the first inverter circuit,
wherein the output of the first inverter circuit is electrically connected to a first wiring through a source and a drain of the first transistor,
wherein the output of the second inverter circuit is electrically connected to a second wiring through a source and a drain of the second transistor,
wherein the second memory circuit comprises a third transistor, a fourth transistor, a fifth transistor, a sixth transistor, and a seventh transistor and a capacitor,
wherein one of a source and a drain of the third transistor is electrically connected to the output of the first inverter circuit and one of a source and a drain of the fourth transistor,
wherein the other of the source and the drain of the third transistor is electrically connected to one terminal of the capacitor and a gate of the fourth transistor,
wherein one of a source and a drain of the fifth transistor is electrically connected to the output of the second inverter circuit and one of a source and a drain of the sixth transistor,
wherein the other of the source and the drain of the fifth transistor is electrically connected to the other terminal of the capacitor and a gate of the sixth transistor,
wherein a gate of the third transistor is electrically connected to a gate of the fifth transistor,
wherein the other of the source and the drain of the fourth transistor and the other of the source and the drain of the sixth transistor are electrically connected to one of a source and a drain of the seventh transistor, and
wherein the other of the source and the drain of the seventh transistor is electrically connected to a third wiring.

5. The semiconductor device according to claim 4,
wherein the first inverter circuit comprises a transistor comprising silicon in a channel formation region,
wherein the second inverter circuit comprises a transistor comprising silicon in a channel formation region, and
wherein the third transistor and the fifth transistor are each a transistor comprising an oxide semiconductor in a channel formation region.

6. The semiconductor device according to claim 4,
wherein the third transistor, the fourth transistor, the fifth transistor, the sixth transistor, and the seventh transistor are each a transistor comprising an oxide semiconductor in a channel formation region.

7. The semiconductor device according to claim 4,
wherein the semiconductor device is configured to output first potential when a potential of the output of the first inverter circuit is the first potential and a potential of the gate of the fourth transistor is the first potential.

8. The semiconductor device according to claim 4,
wherein the semiconductor device is configured to output a second potential when a potential of the output of the first inverter circuit is the second potential and a potential of the gate of the fourth transistor is a first potential, and
wherein the first potential is higher than the second potential.

9. The semiconductor device according to claim 4,
wherein the first memory circuit and the second memory circuit overlap with each other in a region.
